(19) United States
(12) Patent Application Publication
(10) Pub. No.: US 2018/0233385 A1
(43) Pub. Date: Aug. 16, 2018

(54) SUPPORT BODY SEPARATING DEVICE AND SUPPORT BODY SEPARATING METHOD

(71) Applicant: Tokyo Ohka Kogyo Co., Ltd., Kawasaki-shi (JP)

(72) Inventor: Yasumasa IWATA, Kawasaki-shi (JP)

(21) Appl. No.: 15/751,330

(22) PCT Filed: Jul. 26, 2016
(86) PCT No.: PCT/JP2016/071915

§ 371 Date: Feb. 8, 2018

(30) Foreign Application Priority Data
Aug. 11, 2015 (JP) 2015-159253

(51) Int. Cl. H01L 21/67; H01L 21/687; H01L 21/683; B32B 43/00

(52) U.S. Cl. CPC H01L 21/67092; H01L 21/68721; H01L 21/68742; H01L 21/6838; B32B 2457/14; B32B 43/006; H01L 2221/68381; H01L 21/6836; H01L 2221/68327; H01L 21/6835

(57) ABSTRACT

A supporting member separation apparatus including a light emitting section configured to emit light through a support plate to at least a partial region of a peripheral portion of a release layer so as to alter the region, a first holding section configured to, in such a manner as to form a gap between a portion of a substrate and a portion of the support plate which portions sandwich the region as altered, hold the support plate from a side of a surface portion of the support plate which surface portion is opposite to a surface portion of the support plate which surface portion faces the region as altered and lift the support plate, and a fluid nozzle configured to inject a fluid into the layered body through the gap in such a manner as to separate the support plate from the layered body.

### TECHNICAL FIELD

The present invention relates to a supporting member separation apparatus and a supporting member separation method.

### BACKGROUND ART

In recent years, thinning, miniaturization, weight reduction, and the like of electronic devices such as an IC card or a cellular phone have been required. To meet these requirements, it is required that thin semiconductor chips be also used as the semiconductor chips incorporated. For this reason, though a thickness (film thickness) of a wafer substrate which is a base of the semiconductor chip is 125 μm to 150 μm at present, it is known that a thickness of 25 μm to 50 μm is required to be used in the chip for the next generation. Therefore, to obtain the wafer substrate having the film thickness described above, a thinning step of the wafer substrate is essential.

Since the strength of the wafer substrate is reduced by thinning, to prevent a thinned wafer substrate from being damaged, during a production process, a structure such as a circuit is mounted on the wafer substrate while automatically transferring in a state in which a support plate is attached to the wafer substrate. Then, after the production process, the wafer substrate and the support plate are separated from each other. Various methods for stripping a support from a wafer have been used thus far.

Patent Literature 1 discloses a stripping apparatus including (i) a cutting mechanism having a pointed tip which cutting mechanism is configured to, for formation of a cut, be inserted into a combined substrate sideways along a joint surface at which a substrate to be processed and a support substrate are joined with each other and (ii) a fluid supplying mechanism configured to supply a fluid into the combined substrate sideways along the joint surface.

### CITATION LIST

### Patent Literature

[Patent Literature 1]

Japanese Patent Application Publication, Tokukai, No. 2013-219328 (Publication date: Oct. 24, 2013)

### SUMMARY OF INVENTION

### Technical Problem

The stripping apparatus disclosed in Patent Literature 1 dissolves an adhesive layer with use of a solvent supplied by the fluid supplying mechanism and simultaneously separates the support from the rest of the layered body with use of the cutting mechanism. This method unfortunately requires an extended period of time to separate a substrate.

The stripping apparatus disclosed in Patent Literature 1 may also damage the support when separating the support from the rest of the layered body with use of the cutting mechanism.

The present invention has been accomplished in view of the above issues. It is an object of the present invention to provide (i) a supporting member separation apparatus capable of successfully separating a support from the rest of a layered body within a short time period without damaging a substrate or the support and (ii) techniques related to the supporting member separation apparatus.

### Solution to Problem

In order to attain the above object, a supporting member separation apparatus according to the present invention is a supporting member separation apparatus configured to separate, from a layered body, a support that transmits light, the layered body including (i) a substrate, (ii) the support, and between the substrate and the support, (iii) at least a release layer that becomes altered in response to light irradiation, the supporting member separation apparatus including: a light emitting section configured to emit light through the support to at least a partial region of a peripheral portion of the release layer so as to alter the partial region; at least one first holding section configured to, in such a manner as to form a gap between a portion of substrate and a portion of the support which portions sandwich the partial region as altered, (i) hold the support from a side of a surface portion of the support which surface portion is opposite to a surface portion of the support which surface portion faces the partial region as altered and (ii) lift the support; and a fluid injecting section configured to inject a fluid into the layered body through the gap in such a manner as to separate the support from the layered body.

A supporting member separation method according to the present invention is a supporting member separation method for separating, from a layered body, a support that transmits light, the layered body including (i) a substrate, (ii) the support, and between the substrate and the support, (iii) at least a release layer that becomes altered in response to light irradiation, the supporting member separation method including: a light emitting step of emitting light through the support to at least a partial region of a peripheral portion of the release layer so as to alter the partial region; and a separating step of (i) holding the support from a side of a surface portion of the support which surface portion is opposite to a surface portion of the support which surface portion faces the partial region as altered and lifting the support so as to form a gap between a portion of the substrate and a portion of the support which portions sandwich the partial region as altered and (ii) injecting a fluid into the layered body through the gap so as to separate the support from the layered body.

### Advantageous Effects of Invention

The present invention advantageously provides (i) a supporting member separation apparatus capable of successfully separating a support from the rest of a layered body within a short time period without damaging a substrate or the support and (ii) techniques related to the supporting member separation apparatus.

### BRIEF DESCRIPTION OF DRAWINGS

FIG. 1 provides diagrams schematically illustrating a supporting member separation apparatus according to an embodiment (first embodiment) of the present invention.

FIG. 2 provides diagrams schematically illustrating how the supporting member separation apparatus according to an embodiment (first embodiment) of the present invention operates after emitting light to a layered body.

FIG. 3 provides diagrams schematically illustrating a supporting member separation apparatus according to an embodiment (second embodiment) of the present invention.

FIG. 4 provides diagrams schematically illustrating a supporting member separation apparatus according to an embodiment (third embodiment) of the present invention and a supporting member separation apparatus according to a variation of the embodiment.

FIG. 5 provides diagrams schematically illustrating a supporting member separation apparatus according to an embodiment (fourth embodiment) of the present invention.

### DESCRIPTION OF EMBODIMENTS

<Supporting Member Separation Apparatus According to a First Embodiment>

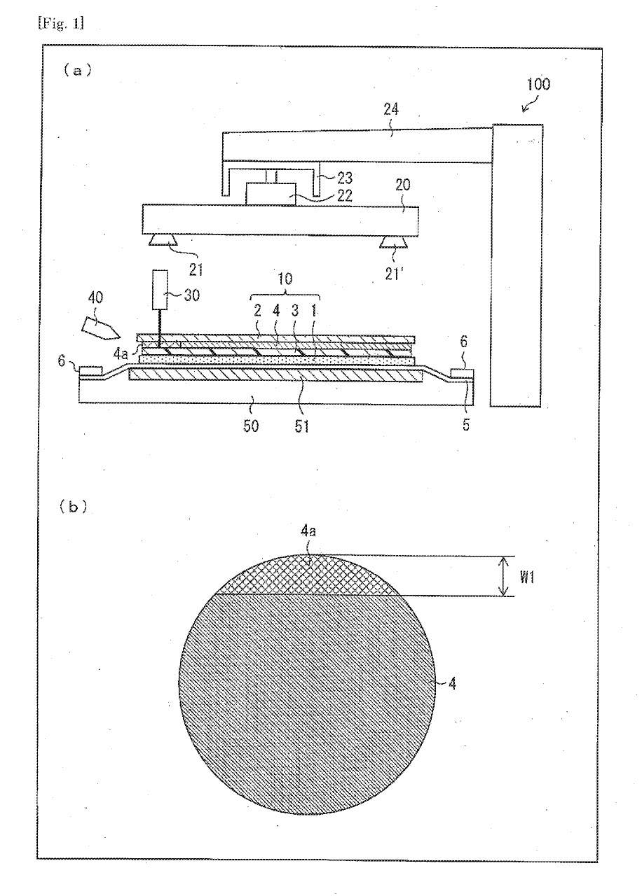

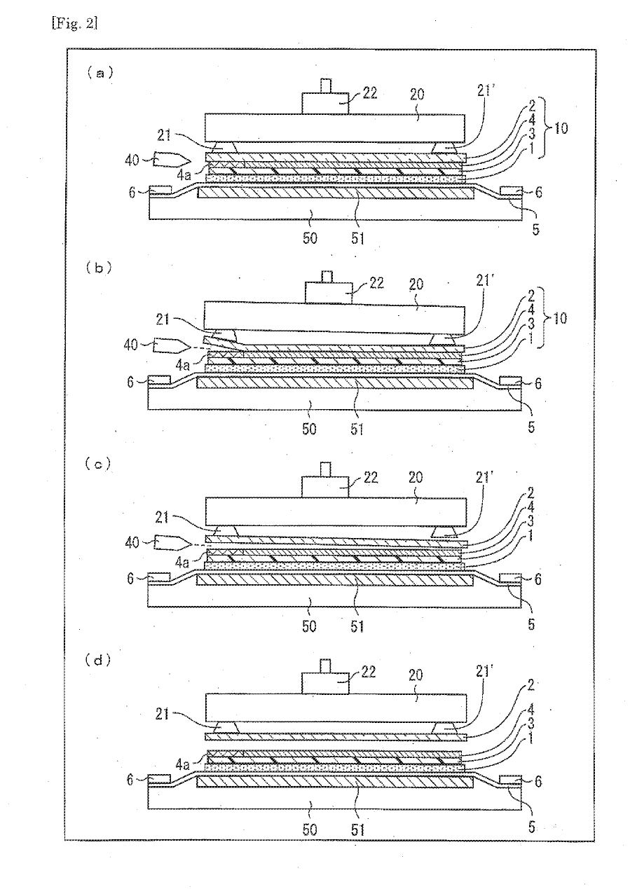

A supporting member separation apparatus 100 according to one embodiment (first embodiment) of the present invention will be described in more detail with reference to FIGS. 1 and 2. (a) of FIG. 1 is a diagram schematically illustrating the supporting member separation apparatus 100. (b) of FIG. 1 is a diagram schematically illustrating a region 4a of a release layer 4 in a layered body 10 to which region 4a a light emitting section 30 included in the supporting member separation apparatus 100 emits light. (a) to (d) of FIG. 2 are each a diagram schematically illustrating how the supporting member separation apparatus 100 operates after the light emitting section 30 emits light to the release layer 4. (a) to (d) of FIG. 2 omit the light emitting section 30 and the lifting and lowering section 24 illustrated in (a) of FIG. 1.

As illustrated in (a) of FIG. 1, the supporting member separation apparatus 100 according to the present embodiment includes a plate section 20 that is provided with a first holding section 21 and a second holding section 21′ and that is connected to the lifting and lowering section 24.

The supporting member separation apparatus 100 further includes a light emitting section 30, a fluid nozzle (fluid injecting section) 40, and a stage (fixing section) 50. The stage 50 includes a porous portion 51 for fixing a layered body 10. The layered body 10 includes a substrate 1, a support plate (support) 2, an adhesive layer 3, and a release layer 4, which are stacked in such a manner that the substrate 1 and the support plate 2 sandwich the release layer 4 and the adhesive layer 3. The release layer 4 becomes altered by absorbing light. In FIGS. 1 and 2, the substrate 1 in the layered body 10 adheres to a dicing tape 5 provided with a dicing frame 6.

[Light Emitting Section 30]

As illustrated in (a) of FIG. 1, the light emitting section 30 emits light to the release layer 4 in the layered body 10 through the support plate 2, which transmits light. This alters the release layer 4.

As illustrated in (b) of FIG. 1, the light emitting section 30 scans the layered body 10 and emits light through the support plate 2 to the region 4a of the release layer 4 in the layered body 10, which has a circular shape in a top view. The substrate 1 has a region facing the region 4a of the release layer 4 which region is a non-circuitry region, in which no structures such as an integrated circuit are present. The region of the substrate 1 other than the region facing the region 4a is a region in which structures such as an integrated circuit are present (circuitry region). Altering only the region 4a of the release layer 4 can prevent light from being emitted to the region other than the region facing the region 4a, that is, the circuitry region of the substrate 1. This makes it possible to alter the region 4a of the release layer 4 and prevent light from being emitted from the light emitting section 30 to the circuitry region of the substrate 1, thereby preventing the light from damaging the circuitry region of the substrate 1.

As illustrated in (b) of FIG. 1, the region 4a, to which the light emitting section 30 emits light, has a width W1 extending inward from the outer peripheral edge of the release layer 4 which width W1 is preferably within a range of not less than 0.5 mm and not more than 8 mm, more preferably within a range of not less than 1.5 mm and not more than 8 mm. A width W1 of not less than 6 mm makes it possible to (i) form a gap between a portion of the substrate 1 which portion corresponds to the region 4a of the release layer 4 and a portion of the support plate 2 which portion corresponds to the region 4a of the release layer 4 and (ii) inject a fluid into the layered body 10 through the gap to successfully separate the support plate 2 from the rest of the layered body 10. A width W1 of not more than 2 mm allows the region 4a of the release layer 4, to which region 4a light is emitted, to have a small area, thereby allowing light to be emitted to only a small area of the substrate 1.

In the specification, the term “alter” used for the release layer refers to a phenomenon in which the release layer becomes a state in which the release layer may be broken by a slight external force, or a state in which the adhesive force between the release layer and the layers in contact with the release layer is decreased. As a result of alteration of the release layer generated by absorbing infrared radiation, the release layer loses the strength or the adhesive property it used to have before being irradiated with light. That is, by absorbing light, the release layer 4 becomes brittle. “Alteration” of the release layer can be that in the release layer, decomposition, change in the configuration thereof, or dissociation of the functional group thereof occurs by the energy of the light absorbed. The alteration of the release layer 4 occurs as a result of absorption of light.

Accordingly, by altering the release layer so as to be broken, for example, by only lifting the support plate, it is possible to easily separate the support plate from the substrate. More specifically, for example, using a supporting member separation apparatus or the like, one of the substrate and the support plate of the layered body is fixed on the fixing section, and the support plate may be separated from the substrate by holding and lifting another one by a suction pad (a holding means) having a suction means, or the support plate may be separated from the substrate by applying a force by gripping the beveled portion of the end portion of the peripheral portion of the support plate by a release plate having a clamp (claw portion) or the like. In addition, for example, the support plate may be stripped from the substrate of the layered body using the supporting member separation apparatus including a stripping means which supplies a stripping solution for stripping the adhesive. The adhesive layer of the layered body swells by supplying the stripping solution to at least a part of the peripheral end portion of the adhesive layer of the layered body by the stripping means, then, a force is concentrated on the release layer from the place where the adhesive layer swelled, and as a result, a force can be applied to the substrate and the support plate. Thus, it is possible to suitably separate the support plate from the substrate.

Moreover, the force applied to the layered body may be suitably adjusted as appropriate depending on, for example, the size of the layered body. Although the force is not limited, in the case of a layered body having a diameter of about 300 mm, applying a force of about 0.1 kgf to 5 kgf can suitably separate the substrate and the support plate from each other.

The light that the light emitting section 30 emits to the release layer 4 may be selected as appropriate depending on the absorption wavelength of the release layer 4. Examples of the laser for emitting light with which the release layer 4 is irradiated include (i) solid lasers such as a YAG laser, a ruby laser, a glass laser, a YVO₄ laser, an LD laser, a fiber laser, and the like, (ii) liquid lasers such as a dye laser and the like, (iii) gas lasers such as a CO₂ laser, an excimer laser, an Ar laser, a He—Ne laser, and the like, (iv) a semiconductor laser, and (v) a free electron laser, as well as non-laser light. A laser for emitting light with which the release layer 4 is irradiated can be suitably selected as appropriate depending on the material of the release layer 4, and a laser that emits light having a wavelength that can alter materials constituting the release layer 4 may be selected.

[Plate Section 20]

The plate section 20 includes a plate circular in a top view which plate has a diameter substantially equal to the diameter of the layered body. The plate section 20 has a surface facing the support plate 2 in the layered body 10 which surface has a peripheral portion provided with a first holding section 21 and a second holding section 21′. The first holding section 21 and the second holding section 21′ are thus positioned directly above a peripheral portion of the support plate 2 in the layered body 10, which is placed on the stage 50.

[First Holding Section 21]

As illustrated in (a) of FIG. 2, the first holding section 21 is configured to hold the support plate 2 by coming into contact with a surface of a portion of the support plate 2 which surface is opposite to a surface of a portion of the support plate 2 which surface faces the region 4a of the release layer 4 which region 4a has been altered. Then, as illustrated in (b) of FIG. 2, the first holding section 21 lifts that portion of the support plate 2 which coincides with the region 4a of the release layer 4 which region 4a has been altered. The first holding section 21, through this operation, forms a gap between a portion of the substrate 1 and a portion of the support plate 2, which portions sandwich the altered region 4a of the release layer 4.

The supporting member separation apparatus 100 according to the present embodiment is configured to hold and lift the support plate 2 with use of a single first holding section 21. The supporting member separation apparatus 100 injects a fluid into the layered body 10 with use of a fluid nozzle 40 through a gap formed between a portion of the substrate 1 and a portion of the support plate 2, which portions sandwich a single altered region 4a of the release layer 4, to successfully separate the support plate 2 from the rest of the layered body 10 (see (c) of FIG. 2).

The first holding section 21 is configured to hold the support plate 2 by vacuum suction, and may be, for example, a bellows pad. This allows the first holding section 21 to, when lifting the support plate 2 in the layered body 10, suitably hold the support plate 2 even in a case where the support plate 2 has been warped.

The first holding section 21 is configured to, when separating the support plate 2 from the rest of the layered body 10, keep holding the support plate 2 by suction (see (c) of FIG. 2). This can prevent the support plate 2, as separated from the rest of the layered body 10, from being moved away from the supporting member separation apparatus 100 due to the pressure of a fluid injected from the fluid nozzle 40.

[Second Holding Section 21′]

As illustrated in (d) of FIG. 2, the second holding section 21′ is configured to hold the support plate 2 in the layered body 10 by coming into contact with a peripheral portion of the support plate 2. The second holding section 21′ is, in other words, identical to the first holding section 21 in that the second holding section 21′ is configured to hold the support plate 2. The second holding section 21′ may include a vacuum suction and holding means such as a bellows pad similarly to the first holding section 21.

The second holding section 21′ does not hold the support plate 2 by suction before the support plate 2 is separated from the rest of the layered body 10. More specifically, before the support plate 2 is separated from the rest of the layered body 10, the second holding section 21′ simply abuts the support plate 2 and does not hold the support plate 2 by suction or is positioned at a slight distance from the support plate 2 (see (b) of FIG. 2). This allows the pressure of a fluid injected from the fluid nozzle 40 to be applied suitably to an area extending from (i) the end portion of the support plate 2 with which end portion the first holding section 21 is in contact to hold the support plate 2 to (ii) the opposite end portion of the support plate 2. This in turn makes it possible to successfully separate the support plate 2 from the rest of the layered body 10 (see (c) of FIG. 2).

Then, when the support plate 2 separated from the rest of the layered body 10 is carried out of the supporting member separation apparatus 100, the second holding section 21′ holds the support plate 2 by suction. The second holding section 21′ is configured to hold the support plate 2 separated from the rest of the layered body 10 (see (d) of FIG. 2).

FIGS. 1 and 2 each illustrate a single second holding section 21′ at a position in the peripheral portion of the plate section 20 (which has a circular shape in a top view) which position is opposite to the first holding section 21. However, the plate section 20 is preferably provided with a plurality of second holding sections 21′ at respective positions in the peripheral portion of the plate section 20. It is more preferable that (i) the first holding section 21 and the plurality of second holding sections 21′ are separated from the central point of the circular plate section 20 by an equal distance and that (ii) any adjacent two of the first holding section 21 and the plurality of second holding sections 21′ are separated from each other by an equal distance. The first holding section 21 and the plurality of second holding sections 21′ holding the support plate 2 by being in contact with the peripheral portion of the support plate 2 at respective positions separated from each other by an equal distance makes it possible to, when carrying the support plate 2 out of the supporting member separation apparatus 100, hold the support plate 2 stably without letting the support plate 2 shake.

[Lifting and Lowering Section 24]

The lifting and lowering section 24 is configured to lift and lower the first holding section 21, with which the plate section 20 is provided. This operation causes the first holding section 21 holding the support plate 2 to lift the support plate 2 to form a gap between a portion of the substrate 1 and a portion of the support plate 2, which portions sandwich the altered region 4a of the release layer 4.

The lifting and lowering section 24 is lifted to a height to form a gap between the adhesive layer 3 and the support plate 2 in the layered body 10. This height can be adjusted as appropriate depending on, for example, the material and thickness of a support to be separated from the rest of the layered body, and may thus be any value that makes it possible to form a gap of at least approximately not less than 0.1 mm and not more than 2 mm between the adhesive layer 3 and the support plate 2.

[Fluid Nozzle 40]

The fluid nozzle 40 is used to, for the separation of the support plate 2 from the rest of the layered body 10, inject a fluid into the layered body 10 through a gap formed, by lifting the first holding section 21, between a portion of the substrate 1 and a portion of the support plate 2, which portions sandwich the region 4a of the release layer 4.

This makes it possible to apply stress to the support plate 2 for the separation of the support plate 2 through the gap between the support plate 2 and the release layer 4 in the layered body 10 without excessively lifting the support plate 2. The above configuration thus makes it possible to (i) prevent the support plate 2 from being damaged as the support plate 2 adhering to the release layer 4 is warped and (ii) suitably separate the support plate 2 from the rest of the layered body 10.

Examples of the fluid to be injected from the fluid nozzle 40 include a gas, a liquid, and a mixture of two fluids including a gas and a liquid. The fluid is more preferably a gas. The gas may be, for example, at least one selected from the group consisting of air, dry air, nitrogen, and argon. The liquid may be, for example, water such as pure water and ion-exchange water, a solvent for dissolving the adhesive layer 3, or a stripping solution for stripping the release layer 4. The two-component fluid may be, for example, a combination of any of the above gases and any of the above liquids.

The solvent for dissolving the adhesive layer 3 may be any of the solvents mentioned in the “(Diluent solvent)” section below.

Examples of the stripping solution for stripping the release layer 4 include an amine-based compound. As the amine-based compound, it is possible to use at least one compound selected from the group consisting of primary, secondary, or tertiary aliphatic amines, alicyclic amines, aromatic amines, or heterocyclic amines. Among compounds of these organic amines, in particular, alkanolamines such as monoethanolamine, 2-(2-aminoethoxy)ethanol, 2-ethylaminoethanol, and 2-methylaminoethanol (MMA) are suitably used. The stripping solution may be prepared by mixing the amine-based compound with another solvent. The stripping solution may be prepared by mixing the amine-based compound with a solvent mentioned under “(Diluent solvent)”.

The fluid to be injected from the fluid nozzle 40 through a gap formed between the substrate 1 and the support plate 2 in the layered body 10, in a case where the fluid is, for example, a gas, preferably has a pressure of not less than 0.2 MPa. This makes it possible to successfully separate the support plate 2 at once from the rest of the layered body 10 immediately after the injection of the gas. The supporting member separation apparatus 100 according to the present embodiment is thus capable of separating the support plate 2 from the rest of the layered body 10 within a short time period as compared to a case of emitting light to the upper surface of a release layer 4 for separation of a support from the rest of a layered body. The fluid to be injected through a gap formed between the substrate 1 and the support plate 2 has a pressure having no particular upper limit as long as the pressure is, for example, not more than 0.7 MPa.

[Stage 50]

The stage (fixing section) 50 is a member on which to place the layered body 10, and has a porous portion 51. The porous portion 51 communicates with a decompression section (not illustrated in the drawings), and is thereby capable of fixing the layered body 10 by suction. This can prevent the layered body 10 from being lifted even in a case where the first holding section 21 holding the support plate 2 is lifted by the lifting and lowering section 24. The above configuration in turn makes it possible to form a gap suitably between a portion of the substrate 1 and a portion of the support plate 2 which portions sandwich the region 4a in the layered body 10 fixed to the stage 50.

[Other Members]

The supporting member separation apparatus 100 includes, in addition to the above-described members, a floating joint 22, a stopper 23, and an optical alignment device (sensing section) for determining the orientation of the layered body 10.

The floating joint 22 is provided at a central portion on the upper surface of the plate section 20, which has a circular shape in a top view. Connecting the plate section 20 to the lifting and lowering section 24 via the floating joint 22 allows the plate section 20 to rotate and also move in such a manner that the surface of the plate section 20 on which surface the first holding section 21 is provided is inclined with respect to the flat surface of the layered body 10 fixed to the stage 50.

The lifting and lowering section 24 is provided with a stopper 23 as a locking means to prevent the plate section 20 from being inclined more than necessary. Even if the plate section 20 is forced to be inclined more than necessary, the stopper 23 comes into contact with the upper surface of the plate section 20 to prevent the plate section 20 from being inclined more than necessary. Adjusting the inclination of the plate section 20 with use of the floating joint 22 and the stopper 23 makes it possible to (i) hold the support plate 2 with use of the first holding section 21 and also (ii) position the second holding section 21′, which is provided at a position opposite to the first holding section 21 on the plate section 20, so that the second holding section 21′ is not far away from the support plate 2.

The supporting member separation apparatus 100 includes an optical alignment device (not illustrated in the drawings) configured to sense a notch (not illustrated in the drawings) in the support plate 2. This configuration allows the supporting member separation apparatus 100 to determine the orientation of the layered body 10 on the basis of a notch in the support plate 2. Determining the orientation of the layered body 10 in advance and emitting light to the release layer 4 with use of the light emitting section 30 makes it possible to determine the orientation of the region 4a of the release layer 4 in the layered body 10 to which region 4a the light has been emitted.

[Layered Body 10]

The following description will discuss in detail a layered body 10 including a support plate 2 that the supporting member separation apparatus 100 according to the present embodiment illustrated in (a) of FIG. 1 is intended to separate. The layered body 10 includes, as stacked in this order, (i) a substrate 1, (ii) an adhesive layer 3, (iii) a release layer 4 that becomes altered by absorbing light, and (iv) a support plate 2 made of a material that transmits light.

[Substrate 1]

The substrate 1 is combined, with the adhesive layer 3 in-between, with the support plate 2 on which the release layer 4 is provided. The substrate 1 can be subjected to a process such as thinning and mounting while the substrate 1 is being supported by the support plate 2. The substrate 1 is not limited to a silicon wafer substrate, but may be any substrate such as a ceramic substrate, a thin film substrate, and a flexible substrate.

The substrate may have a surface on which structures such as an integrated circuit and a metal bump are mounted.

[Support Plate 2]

The support plate (support) 2 is a support that is configured to support the substrate 1, and is combined with the substrate 1 with the adhesive layer 3 in-between. Thus, the support plate 2 may have a strength necessary to prevent the substrate 1 from being damaged or deformed during a process such as thinning, carrying, or mounting for the substrate 1. The support plate 2 may be a support plate that transmits light for altering the release layer. From the above viewpoint, examples of the support plate 2 include a plate made of glass, silicon, or an acryl-based resin.

The support plate 2 may have a thickness within a range of 300 μm to 1000 μm. A supporting member separation method according to the present embodiment makes it possible to, even in a case where the support is thin as such, separate the support suitably from the rest of the layered body while preventing the support from being damaged.

[Adhesive Layer 3]

The adhesive layer 3 is used to attach the substrate 1 and the support plate 2 to each other.

Examples of the adhesive for the adhesive layer 3 include various adhesives publicly known in the related field such as an acryl-based adhesive, a novolac-based adhesive, a naphthoquinone-based adhesive, a hydrocarbon-based adhesive, a polyimide-based adhesive, an elastomer, and a polysulphone-based adhesive. Preferable examples of the adhesive include a polysulphone-based resin, a hydrocarbon resin, an acryl-styrene-based resin, a maleimide-based resin, an elastomer resin, and a combination thereof.

The thickness of the adhesive layer 3 may be selected as appropriate depending on, for example, (i) the respective kinds of the substrate 1 and the support plate 2 that the adhesive layer 3 is used to attach to each other and (ii) a process to be carried out on the substrate 1 after the attachment. The thickness is, however, within a range of preferably 10 μm to 150 μm, more preferably 15 μm to 100 μm.

The adhesive layer 3 is used to attach the substrate 1 and the support plate 2 to each other. The adhesive layer 3 can be formed by coating the substrate 1 with an adhesive by a method such as a spin coating method, a dipping method, a roller blade method, a spray coating method, or a slit coating method. Instead of directly coating the substrate 1 with an adhesive, the adhesive layer 3 may be formed by, for example, attaching to the substrate 1 a film (so-called dry film) of which both surfaces have been coated with an adhesive in advance.

The adhesive layer 3 is a layer containing an adhesive used for attaching the support plate 2 and the substrate 1 to each other.

Examples of the adhesive for the adhesive layer 3 according to an embodiment of the present invention include various adhesives publicly known in the related field such as an acryl-based adhesive, a novolac-based adhesive, a naphthoquinone-based adhesive, a hydrocarbon-based adhesive, a polyimide-based adhesive, and an elastomer. The description below deals with the composition of a resin contained in the adhesive layer 3 according to the present embodiment.

The resin contained in the adhesive layer 3 may be any resin that has an adhesive property. Examples of the resin include a hydrocarbon resin, an acryl-styrene-based resin, a maleimide-based resin, an elastomer resin, a polysulphone-based resin, and a combination thereof.

(Hydrocarbon Resin)

The hydrocarbon resin is a resin having a hydrocarbon skeleton and prepared by polymerizing a monomer composition. Examples of the hydrocarbon resin include (i) a cycloolefin-based polymer (hereinafter, also referred to as “resin (A)”) and (ii) at least one resin (hereinafter, also referred to as “resin (B)”) selected from the group consisting of a terpene-based resin, a rosin-based resin, and a petroleum resin. The hydrocarbon resin is, however, not limited to the above examples.

The resin (A) may be a resin prepared by polymerizing a monomer component containing a cycloolefin-based monomer. Specific examples include a ring-opened (co)polymer of a monomer component containing a cycloolefin-based monomer and a resin prepared by addition-(co)polymerizing a monomer component containing a cycloolefin-based monomer.

Examples of the cycloolefin-based monomer contained in the monomer component contained in the resin (A) include a bicyclic compound such as norbornene and norbornadiene, a tricyclic compound such as dicyclopentadiene and hydroxy dicyclopentadiene, a tetracyclic compound such as tetracyclododecene, a pentacyclic compound such as a cyclopentadiene trimer, a heptacyclic compound such as tetracyclopentadiene, and an alkyl (such as methyl, ethyl, propyl, or butyl) substituent, an alkenyl (such as vinyl) substituent, an alkylidene (such as ethylidene) substituent, and an aryl (such as phenyl, tolyl, or naphthyl) substituent of the polycyclic compound. Among these, norbornene, tetracyclododecene, or a norbornene-based monomer selected from the group consisting of an alkyl substituent of norbornene or tetracyclododecene is particularly preferable.

The monomer component contained in the resin (A) may contain another monomer that can be copolymerized with the above-described cycloolefin-based monomer, and preferably contains an alkene monomer, for example. Examples of the alkene monomer include ethylene, propylene, 1-butene, isobutene, 1-hexene, and α-olefin. The alkene monomer may be linear or branched.

The cycloolefin monomer is preferably contained as the monomer component for the resin (A) from the viewpoint of a high heat resistance (low pyrolytic property and thermal weight loss property). The proportion of the cycloolefin monomer to all the monomer components for the resin (A) is preferably not less than 5 mol %, more preferably not less than 10 mol %, still more preferably not less than 20 mol %. The proportion of the cycloolefin monomer to all the monomer components for the resin (A) is not particularly limited, but is preferably not more than 80 mol %, more preferably not more than 70 mol %, from the viewpoint of solubility and exposure stability in a solution.

The monomer components for the resin (A) may contain a linear or branched alkene monomer. The proportion of the alkene monomer to all the monomer components for the resin (A) is within a range of preferably 10 mol % to 90 mol %, more preferably 20 mol % to 85 mol %, still more preferably 30 mol % to 80 mol %, from the viewpoint of solubility and flexibility.

It is preferable that as with, for example, a resin prepared by polymerizing a monomer component containing a cycloolefin-based monomer and an alkene monomer, the resin (A) is a resin having no polar group to suppress the generation of gas at high temperature.

The polymerization method, the polymerization conditions, and the like when the monomer component is polymerized are not particularly limited, and may be selected as appropriate according to common methods.

Examples of commercially available products that can be used as the resin (A) include “TOPAS” available from POLYPLASTICS Co., Ltd., “APEL” available from Mitsui Chemicals, Inc., “ZEONOR” and “ZEONEX” available from ZEON CORPORATION, and “ARTON” available from JSR Corporation.

The glass transition temperature (Tg) of the resin (A) is preferably not lower than 60° C., particularly preferably not lower than 70° C. In a case where the glass transition temperature of the resin (A) is not lower than 60° C., it is possible to, in a case where the layered body is exposed to a high temperature environment, further suppress softening of the adhesive layer 3.

The resin (B) is at least one resin selected from the group consisting of a terpene-based resin, a rosin-based resin, and a petroleum resin. Specific examples of the terpene-based resin include a terpene resin, a terpene phenol resin, a denatured terpene resin, a hydrogenated terpene resin, and a hydrogenated terpene phenol resin. Examples of the rosin-based resin include rosin, a rosin ester, hydrogenated rosin, a hydrogenated rosin ester, polymerized rosin, a polymerized rosin ester, and denatured rosin. Examples of the petroleum resin include an aliphatic or aromatic petroleum resin, a hydrogenated petroleum resin, a denatured petroleum resin, an alicyclic petroleum resin, and a coumarone-indene petroleum resin. Among these, a hydrogenated terpene resin and a hydrogenated petroleum resin are more preferable.

The softening point of the resin (B) is not particularly limited, but is preferably within a range of 80° C. to 160° C. In a case where the softening point of the resin (B) is within the range of 80° C. to 160° C., it is possible to, in a case where the layered body is exposed to a high temperature environment, suppress softening, and an adhesive failure does not occur.

The weight average molecular weight of the resin (B) is not particularly limited, but is preferably within a range of 300 to 3,000. In a case where the weight average molecular weight of the resin (B) is not less than 300, the heat resistance is sufficient, and the amount of degasification is reduced under a high temperature environment. In a case where the weight average molecular weight of the resin (B) is not more than 3,000, the dissolution rate of the adhesive layer in a hydrocarbon-based solvent is excellent. This makes it possible to quickly dissolve and remove the residue of the adhesive layer on the substrate after separating the support. The weight average molecular weight of the resin (B) for the present embodiment means a molecular weight in terms of polystyrene as measured by gel permeation chromatography (GPC).

The resin may be a mixture of the resins (A) and (B). Mixing the resins allows the heat resistance to be excellent. The mixing ratio between the resin (A) and the resin (B) is, for example, preferably (A):(B)=80:20 to 55:45 (mass ratio) because the heat resistance under the high temperature environment and flexibility are excellent within this range.

(Acryl-Styrene-Based Resin)

Examples of the acryl-styrene-based resin include a resin polymerized using, as monomers, styrene or a styrene derivative and a (meth)acrylic acid ester.

Examples of the (meth)acrylic acid ester include a (meth)acrylic acid alkyl ester having a chain structure, a (meth)acrylic acid ester having an aliphatic ring, and a (meth)acrylic acid ester having an aromatic ring. Examples of the (meth)acrylic acid alkyl ester having a chain structure include an acryl-based long chain alkyl ester having an alkyl group having 15 to 20 carbon atoms and an acryl-based alkyl ester having an alkyl group having 1 to 14 carbons atoms. Examples of the acryl-based long chain alkyl ester include an alkyl ester of acrylic acid or methacrylic acid in which the alkyl group is an n-pentadecyl group, an n-hexadecyl group, an n-heptadecyl group, an n-octadecyl group, an n-nonadecyl group, or an n-eicosyl group. The alkyl group may be branched.

Examples of the acryl-based alkyl ester having an alkyl group having 1 to 14 carbon atoms include a publicly known acryl-based alkyl ester used in an existing acryl-based adhesive. Examples include an alkyl ester of acrylic acid or methacrylic acid in which the alkyl group is a methyl group, an ethyl group, a propyl group, a butyl group, a 2-ethylhexyl group, an isooctyl group, an isononyl group, an isodecyl group, a dodecyl group, a lauryl group, and a tridecyl group.

Examples of the (meth)acrylic acid ester having an aliphatic ring include cyclohexyl (meth)acrylate, cyclopentyl (meth)acrylate, 1-adamantyl (meth)acrylate, norbornyl (meth)acrylate, isobornyl (meth)acrylate, tricyclodecanyl (meth)acrylate, tetracyclododecanyl (meth)acrylate, and dicyclopentanyl (meth)acrylate. Among these, isobornyl methacrylate and dicyclopentanyl (meth)acrylate are more preferable.

The (meth)acrylic acid ester having an aromatic ring is not particularly limited. Examples of the aromatic ring include a phenyl group, a benzyl group, a tolyl group, a xylyl group, a biphenyl group, a naphthyl group, an anthracenyl group, a phenoxymethyl group, and a phenoxyethyl group. Further, the aromatic ring may have a linear or branched alkyl group having 1 to 5 carbon atoms. Specifically, phenoxyethyl acrylate is preferable.

(Maleimide-Based Resin)

Examples of the maleimide-based resin include a resin obtained by polymerizing, as a monomer, (i) a maleimide having an alkyl group such as N-methyl maleimide, N-ethyl maleimide, N-n-propyl maleimide, N-isopropyl maleimide, N-n-butyl maleimide, N-isobutyl maleimide, N-sec-butyl maleimide, N-tert-butyl maleimide, N-n-pentyl maleimide, N-n-hexyl maleimide, N-n-heptyl maleimide, N-n-octyl maleimide, N-lauryl maleimide, and N-stearyl maleimide, (ii) a maleimide having an aliphatic hydrocarbon group such as N-cyclopropyl maleimide, N-cyclobutyl maleimide, N-cyclopentyl maleimide, N-cyclohexyl maleimide, N-cycloheptyl maleimide, and N-cyclooctyl maleimide, and (iii) an aromatic maleimide having an aryl group such as N-phenyl maleimide, N-m-methyl phenyl maleimide, N-o-methyl phenyl maleimide, and N-p-methyl phenyl maleimide.

For example, it is possible to use, as a resin for an adhesive component, a cycloolefin copolymer that is a copolymer having a repeating unit represented by the following Chemical formula (1) and a repeating unit represented by the following Chemical formula (2).

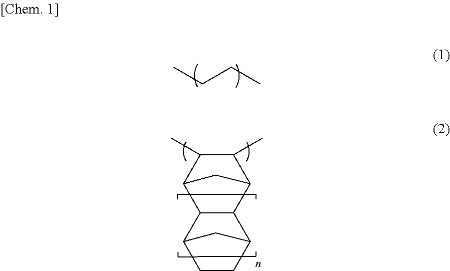

In Chemical formula (2), n represents an integer of 0 or 1 to 3.

Examples of such a cycloolefin copolymer include APL 8008T, APL 8009T, and APL 6013T (all available from Mitsui Chemicals, Inc.).

(Elastomer)

The elastomer preferably contains a styrene unit as a structural unit of a main chain, and the “styrene unit” may have a substituent. Examples of the substituent include an alkyl group having 1 to 5 carbon atoms, an alkoxy group having 1 to 5 carbon atoms, an alkoxyalkyl group having 1 to 5 carbon atoms, an acetoxy group, and a carboxyl group. The content of the styrene unit is more preferably within a range of not less than 14% by weight and not more than 50% by weight. Further, the weight average molecular weight of the elastomer is preferably within a range of not less than 10,000 and not more than 200,000.

In a case where (i) the content of the styrene unit is within the range of not less than 14% by weight and not more than 50% by weight and (ii) the weight average molecular weight of the elastomer is within the range of not less than 10,000 and not more than 200,000, the adhesive layer can be removed more easily and quickly because the elastomer is easily dissolved in a hydrocarbon-based solvent described below. Further, in a case where the content of the styrene unit and the weight average molecular weight are within the above-described ranges, an excellent resistance is exhibited with respect to a resist solvent (for example, PGMEA, PGME, and the like), an acid (hydrofluoric acid and the like), and an alkali (TMAH and the like), to which the wafer is exposed when it is subjected to a resist lithography step.

The above-described (meth)acrylic acid ester may be further mixed in the elastomer.

The content of the styrene unit is more preferably within a range of not less than 17% by weight, more preferably not more than 40% by weight.

The weight average molecular weight is more preferably not less than 20,000. The weight average molecular weight is more preferably not more than 150,000.

The elastomer may be any of various elastomers of which the content of the styrene unit is within the range of not less than 14% by weight and not more than 50% by weight and of which the weight average molecular weight is within the range of not less than 10,000 and not more than 200,000. Examples of the elastomer include a polystyrene-poly(ethylene/propylene) block copolymer (SEP), a styrene-isoprene-styrene block copolymer (SIS), a styrene-butadiene-styrene block copolymer (SBS), a styrene-butadiene-butylene-styrene block copolymer (SBBS), a hydrogenated product thereof, a styrene-ethylene-butylene-styrene block copolymer (SEBS), a styrene-ethylene-propylene-styrene block copolymer (styrene-isoprene-styrene block copolymer) (SEPS), a styrene-ethylene-ethylene-propylene-styrene block copolymer (SEEPS), a styrene-ethylene-ethylene-propylene-styrene block copolymer (SEPTON V9461 [available from KURARAY Co., Ltd.]), SEPTON V9475 (available from KURARAY Co., Ltd.) of which the styrene block is of a reaction crosslinking type, a styrene-ethylene-butylene-styrene block copolymer (having a reactive polystyrene-based hard block, SEPTON V9827 [available from KURARAY Co., Ltd.]) of which the styrene block is of a reaction crosslinking type, and polystyrene-poly(ethylene-ethylene/propylene)block-polystyrene block copolymer (SEEPS-OH: terminal hydroxyl group denaturation). The elastomer may be an elastomer of which the content of the styrene unit and the weight average molecular weight are within the above ranges.

Among the elastomers, a hydrogenated product is more preferable. In the case of the hydrogenated product, stability with respect to heat is improved, and alteration such as decomposition or polymerization is less likely to occur. In addition, the hydrogenated product is more preferable also from the viewpoint of solubility in a hydrocarbon-based solvent and resistance to a resist solvent.

Among the elastomers, an elastomer which is a block polymer having styrene at both terminals is more preferable. This is because a higher heat resistance is exhibited by having, at both terminals, styrene having high heat stability.

More specifically, the elastomer is more preferably a hydrogenated product of a block copolymer of styrene and conjugated diene. This is because stability with respect to heat is improved, and alteration such as decomposition or polymerization is less likely to occur. In addition, a higher heat resistance is exhibited by having, at both terminals, styrene having high heat stability. Furthermore, it is more preferable also from the viewpoint of solubility in a hydrocarbon-based solvent and resistance to a resist solvent.

Examples of commercially available products which can be used as the elastomer contained in the adhesive for the adhesive layer 3 include “SEPTON” (product name) available from KURARAY Co., Ltd., “HYBRAR” (product name) available from KURARAY Co., Ltd., “TUFTEC” (product name) available from Asahi Kasei Corporation, and “DYNARON” (product name) available from JSR Corporation.

The content of the elastomer in the adhesive for the adhesive layer 3 is, for example, preferably within a range of not less than 50 parts by weight and not more than 99 parts by weight, more preferably within a range of not less than 60 parts by weight and not more than 99 parts by weight, most preferably within a range of not less than 70 parts by weight and not more than 95 parts by weight, with respect to 100 parts by weight of the total amount of the adhesive composition. In a case where the content of the elastomer is within the above range, it is possible to suitably attach a wafer and a support to each other while maintaining the heat resistance.

A plurality of types of elastomers may be mixed. In other words, the adhesive for the adhesive layer 3 may contain a plurality of types of elastomers. At least one among the plurality of types of elastomers may contain the styrene unit as a structural unit of a main chain. The present invention covers in its scope any case where at least one of the plurality of types of elastomers contains the styrene unit in an amount within a range of not less than 14% by weight and not more than 50% by weight or has a weight average molecular weight of not less than 10,000 and not more than 200,000. In a case where a plurality of types of elastomers are contained in the adhesive for the adhesive layer 3, the content of the styrene unit may be adjusted so as to be within the above-described range as a result of mixing. For example, in a case where SEPTON 4033 of SEPTON (product name) available from KURARAY Co., Ltd. of which the content of the styrene unit is 30% by weight and SEPTON 2063 of SEPTON (product name) of which the content of the styrene unit is 13% by weight are mixed in a weight ratio of 1:1, the content of styrene with respect to the entire elastomer contained in the adhesive is 21% by weight to 22% by weight, and thus, is not less than 14% by weight. Further, for example, in a case where an elastomer of which the content of the styrene unit is 10% by weight and an elastomer of which the content of the styrene unit is 60% by weight are mixed in a weight ratio of 1:1, the content of styrene is 35% by weight, and thus the content is within the above-described range. The present invention may also be such a form. Further, it is most preferable that all the plurality of types of elastomers contained in the adhesive for the adhesive layer 3 contain the styrene unit within the above-described range and that the weight average molecular weight thereof is within the above-described range.

The adhesive layer 3 is preferably prepared with use of a resin other than a photocurable resin (for example, a UV curable resin). By using a resin other than a photocurable resin, it is possible to prevent residues from remaining around minute unevenness of the substrate 1 after stripping or removing the adhesive layer 3. In particular, the adhesive for the adhesive layer 3 is preferably not an adhesive that is dissolved in all solvents but an adhesive that is dissolved in only a specific solvent. This is because the adhesive layer 3 is removable by dissolving the adhesive layer 3 in the solvent without applying a physical force to the substrate 1. When removing the adhesive layer 3, it is possible to easily remove the adhesive layer 3 without damage or deformation of the substrate 1 even from the substrate 1 of which the strength is reduced.

(Polysulphone-Based Resin)

The adhesive for forming the adhesive layer 3 may contain a polysulfone-based resin. By forming the adhesive layer 3 using a polysulphone-based resin, it is possible to produce a layered body in which the support plate can be stripped from the substrate by dissolving the adhesive layer in a subsequent step, even in the case of treating the layered body at a high temperature. In a case where the adhesive layer 3 contains a polysulphone resin, the layered body can be suitably used even in a high temperature process of treating a layered body at a high temperature of not lower than 300° C. by, for example, annealing or the like.

The polysulphone-based resin has a structure formed of at least one structural unit selected from among the structural unit represented by the following General Formula (3) and the structural unit represented by the following General Formula (4).

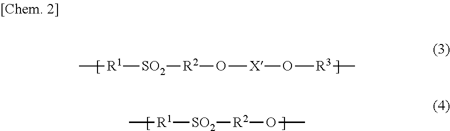

Each of R¹, R², and R³ in General Formula (3), and R¹ and R² in General Formula (4) is independently selected from the group consisting of a phenylene group, a naphthylene group, and an anthrylene group. X′ is an alkylene group having not less than 1 and not more than 3 carbon atoms.

In a case where the polysulphone-based resin has at least one of the polysulphone structural unit represented by Formula (3) and the polyether sulphone structural unit represented by Formula (4), it is possible to form a layered body capable of preventing the adhesive layer 3 from being insolubilized by decomposition, polymerization, or the like even in the case of treating the substrate 1 under a high temperature condition after attaching the support plate 2 to the substrate 1. In a case where the polysulphone-based resin is a polysulphone resin prepared of the polysulphone structural unit represented by Formula (3), the polysulphone-based resin is stable even in a case where it has been heated to a higher temperature. Thus, it is possible to prevent occurrence of residues resulting from the adhesive layer on the substrate 1 after washing.

The weight average molecular weight (Mw) of the polysulphone-based resin is preferably within a range of not less than 30,000 to not more than 70,000, more preferably within a range of not less than 30,000 to not more than 50,000. In a case where the weight average molecular weight (Mw) of the polysulphone-based resin is within a range of not less than 30,000, it is possible to obtain an adhesive composition which can be used at high temperatures of not lower than 300° C., for example. In a case where the weight average molecular weight (Mw) of the polysulphone-based resin is within a range of not more than 70,000, the polysulphone-based resin can be suitably dissolved in a solvent. That is, it is possible to obtain an adhesive composition which can be suitably removed in a solvent.

(Diluent Solvent)

Examples of a diluent solvent used for forming the adhesive layer 3 include a linear hydrocarbon such as hexane, heptane, octane, nonane, methyloctane, decane, undecane, dodecane, and tridecane, a branched hydrocarbon having 4 to 15 carbon atoms, a cyclic hydrocarbon such as cyclohexane, cycloheptane, cyclooctane, naphthalene, decahydronaphthalene, and tetrahydronaphthalene, and a terpene solvent such as p-menthane, o-menthane, m-menthane, diphenylmenthane, 1,4-terpin, 1,8-terpin, bornane, norbornane, pinane, thujane, carane, longifolene, geraniol, nerol, linalool, citral, citronellol, menthol, isomenthol, neomenthol, α-terpineol, β-terpineol, γ-terpineol, terpinene-1-ol, terpinene-4-ol, dihydroterpinylacetate, 1,4-cineol, 1,8-cineol, borneol, carvone, ionone, thujone, camphor, d-limonene, l-limonene, and dipentene; a lactone such as γ-butyrolactone; a ketone such as acetone, methyl ethyl ketone, cyclohexanone (CH), methyl-n-pentyl ketone, methyl isopentyl ketone, and 2-heptanone; a polyalcohol such as ethylene glycol, diethylene glycol, propylene glycol, and dipropylene glycol; a compound having an ester bond such as ethylene glycol monoacetate, diethylene glycol monoacetate, propylene glycol monoacetate, and dipropylene glycol monoacetate, and a derivative of a polyalcohol such as a compound having an ether bond such as a monoalkyl ether such as monomethyl ether, monoethyl ether, monopropyl ether, and monobutyl ether or a monophenyl ether of the polyalcohol or the compound having an ester bond (among these, propylene glycol monomethyl ether acetate (PGMEA) and propylene glycol monomethyl ether (PGME) are preferable); a cyclic ether such as dioxane, or an ester such as methyl lactate, ethyl lactate (EL), methyl acetate, ethyl acetate, butyl acetate, methoxybutyl acetate, methyl pyruvate, ethyl pyruvate, methyl methoxypropionate, and ethyl ethoxypropionate; and an aromatic organic solvent such as anisole, ethylbenzyl ether, cresylmethyl ether, diphenyl ether, dibenzyl ether, phenetole, and butylphenyl ether.

(Other Components)

The adhesive for the adhesive layer 3 may further contain another miscible substance as long as no essential feature is impaired. For example, the adhesive may further contain any of various additives commonly used to improve performance of an adhesive such as an additive resin, a plasticizer, an adhesion auxiliary agent, a stabilizer, a colorant, a thermal polymerization inhibitor, and a surfactant.

[Release Layer 4]

The release layer 4 is a layer made of a material which becomes altered by absorbing light striking the release layer 4 through the support plate 2. The region of the release layer 4 other than the region 4a is also broken when a fluid is injected into the layered body 10 through a gap between the substrate 1 and the support plate 2 as illustrated in (b) of FIG. 2.

The thickness of the release layer 4 is, for example, preferably within a range of not less than 0.05 μm and not more than 50 μm, more preferably within a range of not less than 0.3 μm and not more than 1 μm. In a case where the thickness of the release layer 4 is within a range of not less than 0.05 μm and not more than 50 μm, a desired alteration can be generated at the release layer 4 by irradiation with light for a short period of time and irradiation with light having low energy. Further, the thickness of the release layer 4 is particularly preferably within a range of not more than 1 μm from the viewpoint of productivity.

The layered body 10 may further include another layer between the release layer 4 and the support plate 2. In this case, the other layer may be made of a material which transmits light. This makes it possible to add a layer as appropriate which imparts, for example, a preferable property to the layered body 10 without preventing the incidence of light onto the release layer 4. The wavelength of light which can be used varies depending on the type of material for the release layer 4. Thus, the material for the other layer is not required to transmit all light and can be selected as appropriate from materials which can transmit light having a wavelength that can alter the material of the release layer 4.

The release layer 4 is preferably made only of a material having a structure which absorbs light, but the release layer 4 may be formed with addition of a material not having a structure which absorbs light as long as no essential feature of the present invention is impaired. Further, the surface of the release layer 4 which surface is opposite to the adhesive layer 3 is preferably flat (no irregularities are present). Thus, formation of the release layer 4 can be easily performed, and uniform attachment can be performed at the time of adhesion.

(Fluorocarbon)

The release layer 4 may be made of fluorocarbon. By containing fluorocarbon, the release layer 4 is capable of becoming altered by absorbing light, and as a result, the release layer 4 loses strength or adhesive property it used to have before being irradiated with light. Therefore, by applying a slight external force (for example, lifting the support plate 2), the release layer 4 is broken, and thus, it is possible to easily separate the support plate 2 from the substrate 1. Fluorocarbon for the release layer 4 can be suitably film-formed by plasma chemical vapor deposition (CVD) method.

Fluorocarbon absorbs light having a wavelength within a specific range unique to the type of the fluorocarbon. By irradiating the release layer 4 with light having a wavelength within the range that fluorocarbon contained in the release layer 4 absorbs light, the fluorocarbon can be suitably altered. The light absorptivity of the release layer 4 is preferably not less than 80%.

Examples of the light with which the release layer 4 is irradiated include laser light of, for example, (i) solid lasers such as a YAG laser, a ruby laser, a glass laser, a YVO₄ laser, an LD laser, a fiber laser, and the like, (ii) liquid lasers such as a dye laser and the like, (iii) gas lasers such as a CO₂ laser, an excimer laser, an Ar laser, a He—Ne laser, and the like, (iv) a semiconductor laser, and (v) a free electron laser, as well as non-laser light, depending on the wavelength which can be absorbed by fluorocarbon. The wavelength that can alter fluorocarbon may be a wavelength within a range of, for example, not more than 600 nm, but is not limited thereto.

(Polymer Including, in a Repeating Unit Thereof, a Structure Having a Light Absorption Property)

The release layer 4 may contain a polymer including, in a repeating unit thereof, a structure having a light absorption property. The polymer becomes altered by irradiation with light. The alteration of the polymer occurs when the structure absorbs the light striking the structure. As a result of the alteration of the polymer, the release layer 4 loses the strength or the adhesive property it used to have before being irradiated with light. Therefore, by applying a slight external force (for example, lifting the support plate 2), the release layer 4 is broken, and thus, it is possible to easily separate the support plate 2 from the substrate 1.

The structure having a light absorption property is a chemical structure that, by absorbing light, alters the polymer including the structure as a repeating unit. The structure is, for example, an atomic group including a conjugated n-electron system formed of a substituted or unsubstituted benzene ring, a condensed ring, or a heterocycle. In more detail, the structure may be a cardo structure, a benzophenone structure present at the side chain of the polymer, a diphenyl sulfoxide structure, a diphenyl sulfone structure (bisphenyl sulfone structure), a diphenyl structure, or a diphenylamine structure present at the side chain of the polymer.

In a case where the structure is present at the side chain of the polymer, the structure can be represented by the following formulas.

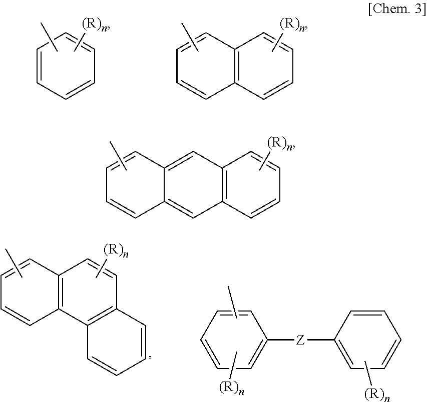

In the formulas, each of R's independently represents an alkyl group, an aryl group, a halogen, a hydroxyl group, a ketone group, a sulfoxide group, a sulfone group, or N(R⁴)(R⁵) (where each of R⁴ and R⁵ independently represents a hydrogen atom or an alkyl group having 1 to 5 carbon atoms); Z is absent or represents —CO—, —SO₂—, —SO—, or —NH—; and n is an integer of 0 or 1 to 5.

The polymer, for example, includes a repeating unit represented by any one of (a) to (d), is represented by (e), or includes the structure of (f) in the main chain, among the following formulas.

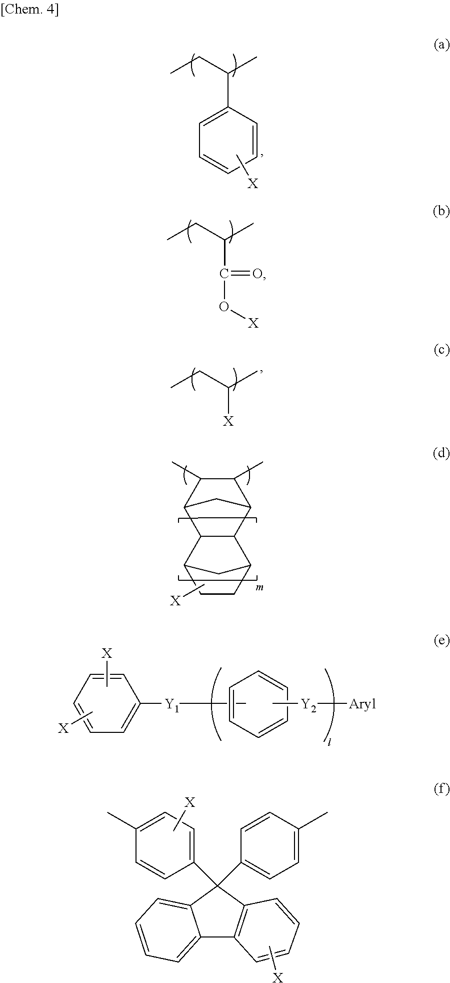

In the formulas, l is an integer of 1 or greater; m is an integer of 0, 1, or 2; X in (a) to (e) is any one of the formulas shown in “Chemical formula 3”; X in (f) is any one of the formulas shown in “Chemical formula 3” or is absent; and each of Y₁ and Y₂ independently represents —CO— or SO₂—. l is preferably an integer of not more than 10.

Examples of the benzene ring, the condensed ring, and the heterocycle shown in [Chem. 3] above include phenyl, substituted phenyl, benzyl, substituted benzyl, naphthalene, substituted naphthalene, anthracene, substituted anthracene, anthraquinone, substituted anthraquinone, acridine, substituted acridine, azobenzene, substituted azobenzene, fluorim, substituted fluorim, fluorimon, substituted fluorimon, carbazole, substituted carbazole, N-alkylcarbazole, dibenzofuran, substituted dibenzofuran, phenanthrene, substituted phenanthrene, pyrene, and substituted pyrene. In a case where the exemplified substituent further has a substituent, the substituent can be selected from, for example, alkyl, aryl, a halogen atom, alkoxy, nitro, aldehyde, cyano, amide, dialkylamino, sulfonamide, imide, carboxylic acid, carboxylic ester, sulfonic acid, sulfonic ester, alkylamino, and arylamino.

Among the substituents shown in [Chem. 3] above, examples of the fifth substituent having two phenyl groups and —SO₂— as Z include bis(2,4-dihydroxyphenyl)sulfone, bis(3,4-dihydroxyphenyl)sulfone, bis(3,5-dihydroxyphenyl)sulfone, bis(3,6-dihydroxyphenyl)sulfone, bis(4-hydroxyphenyl)sulfone, bis(3-hydroxyphenyl)sulfone, bis(2-hydroxyphenyl)sulfone, and bis(3,5-dimethyl-4-hydroxyphenyl)sulfone.

Among the substituents shown in [Chem. 3] above, examples of the fifth substituent having two phenyl groups and —SO— as Z include bis(2,3-dihydroxyphenyl)sulfoxide, bis(5-chloro-2,3-dihydroxyphenyl)sulfoxide, bis(2,4-dihydroxyphenyl)sulfoxide, bis(2,4-dihydroxy-6-methylphenyl)sulfoxide, bis(5-chloro-2,4-dihydroxyphenyl)sulfoxide, bis(2,5-dihydroxyphenyl)sulfoxide, bis(3,4-dihydroxyphenyl)sulfoxide, bis(3,5-dihydroxyphenyl)sulfoxide, bis(2,3,4-trihydroxyphenyl)sulfoxide, bis(2,3,4-trihydroxy-6-methylphenyl)sulfoxide, bis(5-chloro-2,3,4-trihydroxyphenyl)sulfoxide, bis(2,4,6-trihydroxyphenyl)sulfoxide, and bis(5-chloro-2,4,6-trihydroxyphenyl) sulfoxide.

Among the substituents shown in [Chem. 3] above, examples of the fifth substituent having two phenyl groups and —C(═O)— as Z include 2,4-dihydroxybenzophenone, 2,3,4-trihydroxybenzophenone, 2,2′,4,4′-tetrahydroxybenzophenone, 2,2′,5,6′-tetrahydroxybenzophenone, 2-hydroxy-4-methoxybenzophenone, 2-hydroxy-4-octoxybenzophenone, 2-hydroxy-4-dodecyloxybenzophenone, 2,2′-dihydroxy-4-methoxybenzophenone, 2,6-dihydroxy-4-methoxybenzophenone, 2,2′-dihydroxy-4,4′-dimethoxybenzophenone, 4-amino-2′-hydroxybenzophenone, 4-dimethylamino-2′-hydroxybenzophenone, 4-diethylamino-2′-hydroxybenzophenone, 4-dimethylamino-4′-methoxy-2′-hydroxybenzophenone, 4-dimethylamino-2′,4′-dihydroxybenzophenone, and 4-dimethylamino-3′,4′-dihydroxybenzophenone.

In a case where the structure is present at the side chain of the polymer, the proportion occupied by the repeating unit including the structure in the polymer is within a range in which the light transmittance of the release layer 4 is not less than 0.001% and not more than 10%. In a case where a polymer is prepared such that the proportion is within the range, the release layer 4 sufficiently absorbs light, and thus, the polymer can be reliably and quickly altered. That is, it is easy to remove the support plate 2 from the layered body 10, and it is possible to reduce a light irradiation time needed for the removal.

The above structure can absorb light having a wavelength within a desired range through selection of the type thereof. The wavelength of light that can be absorbed by the structure is, for example, more preferably within a range of not less than 100 nm and not more than 2,000 nm. Within the range, the wavelength of light that can be absorbed by the structure is on the shorter wavelength side, and is, for example, within a range of not less than 100 nm and not more than 500 nm. By absorbing ultraviolet light having a wavelength preferably within a range of, for example, about not less than 300 nm and not more than 370 nm, the structure can alter a polymer including the structure.

Examples of the light that can be absorbed by the structure include light emitted by a high-pressure mercury lamp (with a wavelength of not less than 254 nm and not more than 436 nm), a KrF excimer laser (with a wavelength of 248 nm), an ArF excimer laser (with a wavelength of 193 nm), an F₂ excimer laser (with a wavelength of 157 nm), a XeCl laser (with a wavelength of 308 nm), a XeF laser (with a wavelength of 351 nm), or a solid-state UV laser (with a wavelength of 355 nm), a g-line (with a wavelength of 436 nm), an h-line (with a wavelength of 405 nm), and an i-line (with a wavelength of 365 nm).

The above-described release layer 4 contains a polymer including the structure as a repeating unit, and can further include a component other than the polymer. Examples of the component include a filler, a plasticizer, and a component that can improve the stripping property of the support plate 2. These components are selected as appropriate from conventionally publicly known substances or materials which do not inhibit absorption of light by the structure and alteration of the polymer or which promote the absorption of light by the structure and the alteration of the polymer.

(Inorganic Substance)

The release layer 4 may be made of an inorganic substance. By containing an inorganic substance, the release layer 4 is capable of becoming altered by absorbing light, and as a result, the release layer 4 loses the strength or the adhesive property it used to have before being irradiated with light. Therefore, by applying a slight external force (for example, lifting the support plate 2), the release layer 4 is broken, and thus, it is possible to easily separate the support plate 2 from the substrate 1.

The inorganic substance may have a structure which becomes altered by absorbing light. For example, one or more inorganic substances selected from the group consisting of a metal, a metal compound, and carbon can be suitably used. The metal compound refers to a compound including a metal atom, and can be, for example, a metal oxide or a metal nitride. Examples of the inorganic substance include one or more inorganic substances selected from the group consisting of gold, silver, copper, iron, nickel, aluminum, titanium, chromium, SiO₂, SiN, Si₃N₄, TiN, and carbon. The inorganic substance is, however, not limited thereto. The carbon may be an allotrope of carbon. Examples of the allotrope of carbon can include diamond, fullerene, diamond-like carbon, and a carbon nanotube.

The inorganic substance absorbs light having a wavelength within a specific range unique to the type of the inorganic substance. By irradiating the release layer 4 with light having a wavelength within the range that the inorganic substance contained in the release layer 4 absorbs light, the inorganic substance can be suitably altered.

Examples of the light with which the release layer 4 made of an inorganic substance is irradiated include laser light of, for example, (i) solid lasers such as a YAG laser, a ruby laser, a glass laser, a YVO₄ laser, an LD laser, a fiber laser, and the like, (ii) liquid lasers such as a dye laser and the like, (iii) gas lasers such as a CO₂ laser, an excimer laser, an Ar laser, a He—Ne laser, and the like, (iv) a semiconductor laser, and (v) a free electron laser, as well as non-laser light, depending on the wavelength which can be absorbed by the inorganic substance.

The release layer 4 made of an inorganic substance can be formed on the support plate 2 by, for example, a publicly known technique such as sputtering, chemical vapor deposition (CVD), plating, plasma CVD, or spin coating. The thickness of the release layer 4 made of an inorganic substance is not particularly limited, and the thickness may be a film thickness that can sufficiently absorb the light to be used. For example, a film thickness within a range of not less than 0.05 μm and not more than 10 μm is more preferable. Further, after both sides or one side of an inorganic film (for example, a metal film) of an inorganic substance for the release layer 4 is coated with an adhesive in advance, the inorganic film may be attached to the support plate 2 and the substrate 1.

In a case where the metal film is used as the release layer 4, reflection of the laser or charging of the film may occur depending on the conditions such as the film quality of the release layer 4, the type of the laser light source, the laser output, and the like. For this reason, it is preferable to take countermeasures for the problem by providing an antireflection film or an antistatic film on both or either of the upper and lower sides of the release layer 4.

(Compound Having an Infrared Ray Absorbing Structure)

The release layer 4 may be made of a compound having an infrared ray absorbing structure. The compound becomes altered by absorbing infrared rays. As a result of alteration of the compound, the release layer 4 loses the strength and the adhesive property it used to have before being irradiated with infrared rays. Therefore, by applying a slight external force (for example, lifting the support), the release layer 4 is broken, and thus, it is possible to easily separate the support plate 2 from the substrate 1.

Examples of a structure having an infrared ray absorption property and a compound including a structure having an infrared ray absorption property can include alkane, alkene (vinyl, trans, cis, vinylidene, trisubstituted, tetrasubstituted, conjugated, cumulene, or cyclic), alkyne (monosubstituted or disubstituted), a monocyclic aromatic compound (benzene, monosubstituted, disubstituted, or trisubstituted), alcohols and phenols (free OH, an intramolecular hydrogen bond, an intermolecular hydrogen bond, saturated secondary, saturated tertiary, unsaturated secondary, or unsaturated tertiary), acetal, ketal, aliphatic ether, aromatic ether, vinyl ether, oxirane ring ether, ether peroxide, ketone, dialkyl carbonyl, aromatic carbonyl, enol of 1,3-diketone, o-hydroxy aryl ketone, dialkyl aldehyde, aromatic aldehyde, carboxylic acid (dimer or carboxylate anion), formic ester, acetic ester, conjugated ester, non-conjugated ester, aromatic ester, lactone (β-, γ-, or δ-), aliphatic acid chloride, aromatic acid chloride, acid anhydride (conjugated, non-conjugated, cyclic, or acyclic), primary amide, secondary amide, lactam, primary amine (aliphatic or aromatic), secondary amine (aliphatic or aromatic), tertiary amine (aliphatic or aromatic), a primary amine salt, a secondary amine salt, a tertiary amine salt, ammonium ion, aliphatic nitrile, aromatic nitrile, carbodiimide, aliphatic isonitrile, aromatic isonitrile, isocyanic ester, thiocyanic ester, aliphatic isothiocyanic ester, aromatic isothiocyanic ester, an aliphatic nitro compound, an aromatic nitro compound, nitroamine, nitrosoamine, nitric ester, nitrite ester, a nitroso bond (aliphatic, aromatic, monomer, or dimer), sulfur compounds such as mercaptan, thiophenol, and thiol acid, a thiocarbonyl group, sulfoxide, sulfone, sulfonyl chloride, primary sulfonamide, secondary sulfonamide, sulfuric ester, a carbon-halogen bond, a Si-A¹ bond (A¹ is H, C, O, or a halogen), a P-A² bond (A² is H, C, or O), and a Ti—O bond.

Examples of the structure including a carbon-halogen bond include —CH₂Cl, —CH₂Br, —CH₂I, —CF₂—, —CF₃, —CH═CF₂, —CF═CF₂, aryl fluoride, and aryl chloride.

Examples of the structure including a Si-A¹ bond include SiH, SiH₂, SiH₃, Si—CHs, Si—CH₂—, Si—C₆H₅, SiO-aliphatic group, Si—OCH₃, Si—OCH₂CH₃, Si—OC₆H₅, Si—O—Si, Si—OH, SiF, SiF₂, and SiF₃. As the structure including the Si-A¹ bond, a structure in which in particular, a siloxane skeleton or a silsesquioxane skeleton is present is preferable.

Examples of the structure including a P-A² bond include PH, PH₂, P—CH₃, P—CH₂—, P—C₆H₅, A³₃-P—O (where A³ is an aliphatic group or an aromatic group), (A⁴O)₃—P—O (where A⁴ is an alkyl group), P—OCH₃, P—OCH₂CH₃, P—OC₆H₅, P—O—P, P—OH, and O═P—OH.

The above-described structures can absorb infrared rays having a wavelength within a desired range through selection of the type thereof. Specifically, the wavelength of infrared rays that can be absorbed by the structure is, for example, within a range of not less than 1 μm and not more than 20 μm. The structure can more suitably absorb light having a wavelength within a range of not less than 2 μm and not more than 15 μm. Further, in a case where the above-described structure is a Si—O bond, a Si—C bond, or a Ti—O bond, the wavelength may be within a range of not less than 9 μm and not more than 11 μm. Those skilled in the art can easily understand the wavelength of infrared rays that can be absorbed by each structure. For example, as an absorption band in each structure, the description in pp. 146 to 151 of non-patent literature “Spectrometric identification of organic compounds—combined use of MS, IR, NMR, UV—(5th edition)”, written by Silverstein, Bassler and Morrill (published in 1992), can be referred to.

The compound having an infrared ray absorbing structure, used in the formation of the release layer 4, is not particularly limited as long as the compound has the structure described above, can be dissolved in a solvent so as to be applied, and can form a solid layer by being solidified. However, in order to easily separate the support plate 2 from the substrate 1 by effectively altering the compound in the release layer 4, it is preferable that the absorption of infrared rays by the release layer 4 is high, that is, the transmittance of infrared rays when the release layer 4 is irradiated with the infrared rays is low. Specifically, the transmittance of infrared rays by the release layer 4 is preferably less than 90%, and the transmittance of infrared rays is more preferably less than 80%.

For example, the compound having a siloxane skeleton may be (i) a resin which is a copolymer having a repeating unit represented by the following Chemical formula (5) and a repeating unit represented by the following Chemical formula (6) or (ii) a resin which is a copolymer having a repeating unit represented by the following Chemical formula (5) and a repeating unit derived from an acryl-based compound.

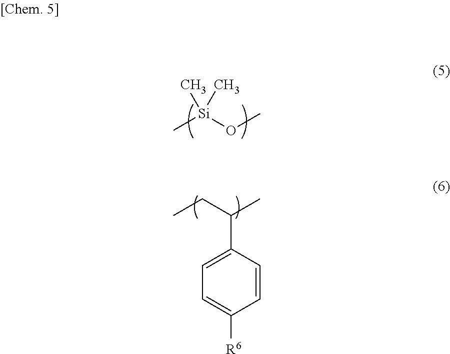

In Chemical formula (6), R⁶ represents hydrogen, an alkyl group having not more than 10 carbon atoms, or an alkoxy group having not more than 10 carbon atoms.

Among these, the compound having a siloxane skeleton is more preferably a tert-butylstyrene (TBST)-dimethylsiloxane copolymer which is a copolymer having the repeating unit represented by Chemical formula (5) and the repeating unit represented by Chemical formula (7), still more preferably a TBST-dimethylsiloxane copolymer which includes the repeating unit represented by Chemical formula (5) and the repeating unit represented by the following Chemical formula (7) at a ratio of 1:1.

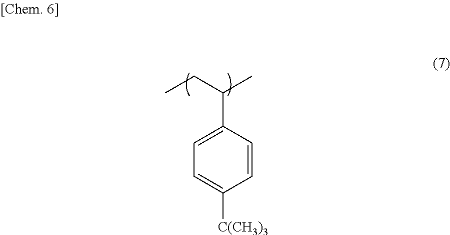

The compound having a silsesquioxane skeleton may be, for example, a resin which is a copolymer having the repeating unit represented by the following Chemical formula (8) and the repeating unit represented by the following Chemical formula (9).

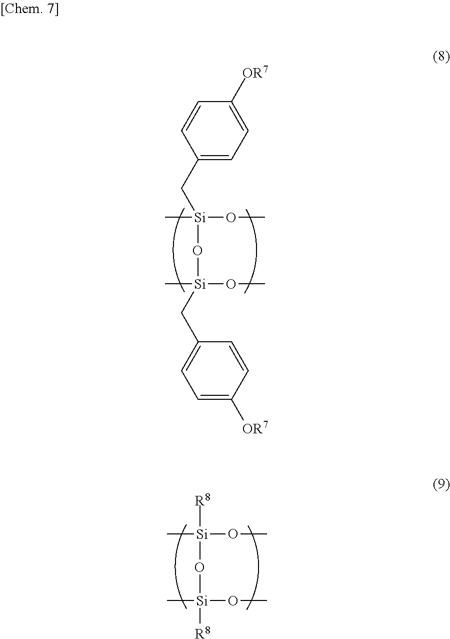

In Chemical Formula (8), R⁷ represents hydrogen or an alkyl group having not less than 1 and not more than 10 carbon atoms. In Chemical Formula (9), R⁸ represents an alkyl group having not less than 1 and not more than 10 carbon atoms or a phenyl group.

In addition to the above compounds, the compound having a silsesquioxane skeleton may suitably be any of silsesquioxane resins disclosed in Japanese Patent Application Publication, Tokukai, No. 2007-258663 (published in Oct. 4, 2007), Japanese Patent Application Publication, Tokukai, No. 2010-120901 (published in Jun. 3, 2010), Japanese Patent Application Publication, Tokukai, No. 2009-263316 (published in Nov. 12, 2009), and Japanese Patent Application Publication, Tokukai, No. 2009-263596 (published in Nov. 12, 2009).

Among these, the compound having a silsesquioxane skeleton is more preferably a copolymer having the repeating unit represented by the following Chemical formula (10) and the repeating unit represented by the following Chemical formula (11), still more preferably a copolymer which includes the repeating unit represented by the following Chemical formula (10) and the repeating unit represented by the following Chemical formula (11) at a ratio of 7:3.

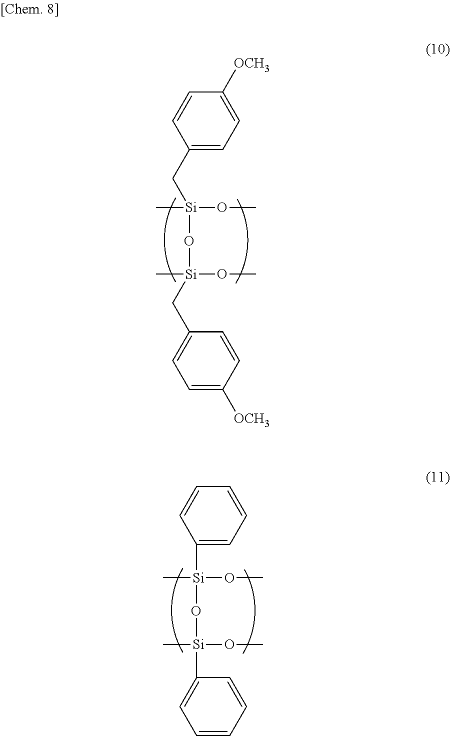

Although the polymer having a silsesquioxane skeleton can have a random structure, a ladder structure, or a basket structure, the polymer may have any structure.

Examples of the compound including a Ti—O bond include (i) an alkoxy titanium such as tetra-i-propoxy titanium, tetra-n-butoxy titanium, tetrakis(2-ethylhexyloxy)titanium, and titanium-i-propoxy octylene glycolate; (ii) a chelate titanium such as di-i-propoxy bis(acetylacetonato)titanium and propanedioxy titanium bis(ethyl acetoacetate); (iii) a titanium polymer such as i-C₃H₇O—[—Ti(O-i-C₃H₇)₂—O-]ₙ-i-C₃H₇ and n-C₄H₉O—[—Ti(O-n-C₄H₉)₂—O-]n-n-C₄H₉; (iv) a titanium acylate such as tri-n-butoxy titanium monostearate, titanium stearate, di-i-propoxy titanium diisostearate, and (2-n-butoxycarbonyl benzoyloxy)tributoxy titanium; and (v) a water-soluble titanium compound such as di-n-butoxy bis(triethanolaminato)titanium.

Among these, the compound including a Ti—O bond is preferably di-n-butoxy-bis(triethanolaminato)titanium (Ti(OC₄H₉)₂[OC₂H₄N(C₂H₄OH)₂]₂).

The release layer 4 described above includes a compound having an infrared ray absorbing structure, and can further contain a component other than the above-described compounds. Examples of the component include a filler, a plasticizer, and a component that can improve the stripping property of the support plate 2. These components are selected as appropriate from conventionally publicly known substances or materials which do not inhibit absorption of infrared rays by the structure and alteration of compounds or which promote the absorption of infrared rays by the structure and the alteration of compounds.

(Infrared Ray Absorbing Substance)

The release layer 4 may contain an infrared ray absorbing substance. By containing an infrared ray absorbing substance, the release layer 4 is capable of becoming altered by absorbing light, and as a result, the release layer 4 loses the strength or the adhesive property it used to have before being irradiated with light. Therefore, by applying a slight external force (for example, lifting the support plate 2), the release layer 4 is broken, and thus, it is possible to easily separate the support plate 2 from the substrate 1.

The infrared ray absorbing substance may have a structure which becomes altered by absorbing infrared rays. For example, carbon black, iron particles, or aluminum particles can be suitably used. The infrared ray absorbing substance absorbs light having a wavelength within a specific range unique to the type of the infrared ray absorbing substance. By irradiating the release layer 4 with light having a wavelength within the range that the infrared ray absorbing substance contained in the release layer 4 absorbs, the infrared ray absorbing substance can be suitably altered.

(Reactive Polysilsesquioxane)

The release layer 4 can be formed by polymerizing a reactive polysilsesquioxane. This allows the release layer 4 to have a high chemical resistance and a high heat resistance.

In the present specification, the reactive polysilsesquioxane is polysilsesquioxane having, at a terminal of the polysilsesquioxane skeleton, a silanol group or a functional group capable of forming a silanol group by hydrolysis. By condensing the silanol group or the functional group capable of forming a silanol group, the polysilsesquioxane can be polymerized with each other. Further, in a case where a reactive polysilsesquioxane has a silanol group or a functional group capable of forming a silanol group, it is possible to employ a reactive polysilsesquioxane having a silsesquioxane skeleton such as a random structure, a basket structure, or a ladder structure.

The reactive polysilsesquioxane more preferably has the structure represented by the following formula (12).

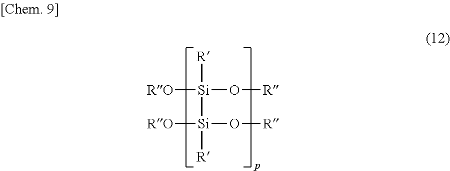

In Formula (12), each R″ is independently selected from the group consisting of hydrogen and an alkyl group having not less than 1 and not more than 10 carbon atoms, more preferably selected from the group consisting of hydrogen and an alkyl group having not less than 1 and not more than 5 carbon atoms. In a case where R″ is hydrogen or an alkyl group having not less than 1 and not more than 10 carbon atoms, it is possible to suitably condense the reactive polysilsesquioxane represented by Formula (12) by heating in the release layer forming step.

In Formula (12), p is preferably an integer of 1 to 100, more preferably an integer of 1 to 50. Since the reactive polysilsesquioxane has the repeating unit represented by Formula (12), the reactive polysilsesquioxane has a higher content of the Si—O bond than that formed by using other materials. It is thus possible to form a release layer 4a having high absorbance for infrared rays (not less than 0.78 μm and not more than 1000 μm), preferably for far infrared rays (not less than 3 μm and not more than 1000 μm), more preferably for light having a wavelength of not less than 9 μm and not more than 11 μm.

Further, in Formula (12), each R′ independently represents an organic group which is identical to or different from another R′. R is, for example, an aryl group, an alkyl group, or an alkenyl group, and any of these organic groups may have a substituent.

In a case where R′ is an aryl group, examples of the aryl group include a phenyl group, a naphthyl group, an anthryl group, and a phenanthryl group, and a phenyl group is more preferable. The aryl group may be bonded to a polysilsesquioxane skeleton via an alkylene group having 1 to 5 carbon atoms.

In a case where R is an alkyl group, examples of the alkyl group include a linear alkyl group, a branched alkyl group, and a cyclic alkyl group. In the case where R′ is an alkyl group, an alkyl group having 1 to 15 carbon atoms is preferable, and an alkyl group having 1 to 6 carbon atoms is more preferable. in a case where R is a cyclic alkyl group, the cyclic alkyl group may be an alkyl group having a monocyclic or bi- to tetracyclic structure.

In a case where R′ is an alkenyl group, examples of the alkenyl group can include a linear alkenyl group, a branched alkenyl group, and a cyclic alkenyl group similar to the case of the alkyl group. The alkenyl group preferably has 2 to 15 carbon atoms, more preferably 2 to 6 carbon atoms. In a case where R is a cyclic alkenyl group, the cyclic alkenyl group may be an alkenyl group having a monocyclic or bi- to tetracyclic structure. Examples of the alkenyl group can include a vinyl group and an allyl group.

Examples of the substituent which may be included in R′ can include a hydroxyl group and an alkoxy group. In a case where the substituent is an alkoxy group, examples of the alkoxy group can include a linear alkylalkoxy group, a branched alkylalkoxy group, and a cyclic alkylalkoxy group. The alkoxy group preferably has 1 to 15 carbon atoms, more preferably 1 to 10 carbon atoms.

From one viewpoint, the siloxane content of the reactive polysilsesquioxane is preferably not less than 70 mol % and not more than 99 mol %, more preferably not less than 80 mol % and not more than 99 mol %. In a case where the siloxane content of the reactive polysilsesquioxane is not less than 70 mol % and not more than 99 mol %, it is possible to form a release layer which can be suitably altered by irradiation with infrared rays (preferably, far infrared rays, more preferably light having a wavelength of not less than 9 μm and not more than 11 μm).

From one viewpoint, the weight average molecular weight (Mw) of the reactive polysilsesquioxane is preferably not less than 500 and not more than 50,000, more preferably not less than 1,000 and not more than 10,000. In a case where the weight average molecular weight (Mw) of the reactive polysilsesquioxane is not less than 500 and not more than 50,000, it is possible to (i) suitably dissolve the reactive polysilsesquioxane in a solvent and (ii) suitably coat the support with the reactive polysilsesquioxane.

Examples of commercially available products that can be used as the reactive polysilsesquioxane can include SR-13, SR-21, SR-23, and SR-33 available from KONISHI CHEMICAL IND. CO., Ltd.

[Variation of Layered Body: 1]

A layered body from which a supporting member separation apparatus separates a support includes (i) a substrate, (ii) a support that transmits light, and between the substrate and the support, (iii) at least a release layer that becomes altered in response to light irradiation. A layered body for the present invention may thus be a layered body including an adhesive layer between a release layer and a substrate as described above or a layered body including no adhesive layer between a release layer and a substrate. A layered body including no adhesive layer may be, for example, a layered body including a substrate, a support, and between the substrate and the support, a release layer that has adhesiveness. Examples of a release layer that has adhesiveness include (i) a release layer made of a curable or thermoplastic resin that absorbs light and (ii) a release layer made of a combination of an adhesive resin and a material that absorbs light. A release layer made of a curable or thermoplastic resin that absorbs light may be, for example, a release layer made of polyimide resin. A release layer made of a combination of an adhesive resin and a material that absorbs light may be, for example, a release layer made of a combination of an acryl-based ultraviolet-curable resin and carbon black or a release layer made of a combination of an adhesive resin and an infrared-absorbing material with glass bubbles. These release layers are each, regardless of whether it is adhesive, a release layer for the present invention that becomes altered in response to light irradiation.

[Variation of Layered Body: 2]

The first embodiment uses a layered body 10 including a support plate 2, an adhesive layer 3, and a release layer 4 between the support plate 2 and the adhesive layer 3. In a case where the adhesive layer has an adhesive force that allows the support plate 2 to be stripped off by a mechanical force, the supporting member separation apparatus described for the first embodiment may be used to separate the support plate even if the layered body does not include a release layer and includes an adhesive layer in direct contact with the substrate and the support plate.

The supporting member separation apparatus 100 described for the first embodiment may, in other words, be a supporting member separation apparatus 100 configured to separate a support plate 2 from a layered body including a substrate 1, the support plate 2, and an adhesive layer 3 between the substrate 1 and the support plate 2, the support plate 2 supporting the substrate 1, the supporting member separation apparatus 100 including: a stage 50 configured to fix the layered body on the side of the substrate 1; a first holding section 21 configured to, in such a manner as to form a gap between a portion of the substrate 1 and a portion of the support plate 2 which portions sandwich a portion of the adhesive layer 3, (i) hold the support plate 2 from the side of a surface portion of the support plate 2 which surface portion is opposite to a surface portion of the support plate 2 which surface portion faces the portion of the adhesive layer 3 and (ii) lift the support plate 2; and a fluid nozzle 40 configured to inject a fluid into the layered body through the gap in such a manner as to separate the support plate 2 from the layered body. In this case, the first holding section 21 is preferably configured to clamp and lift an outer peripheral edge of the support plate 2 so as to form the gap.

Examples of an adhesive of which an adhesive layer may be made that has an adhesive force that allows a support to be stripped off by a mechanical force include a pressure sensitive adhesive and a strippable adhesive. Examples of the pressure sensitive adhesive (tackiness agent) include any publicly known pressure sensitive adhesive containing a synthetic rubber such as latex rubber, acrylic rubber, and isoprene rubber or a tackifier resin. Examples of the strippable adhesive include an adhesive containing a combination of a thermoplastic resin, a photocurable resin, a thermosetting resin, or the like and a release agent such as wax and silicone to have an adjusted adhesive force. The strippable adhesive may be a curable adhesive that contains a thermosetting resin, a photocurable resin, or the like and that exhibits its strippability through curing of the resin. The strippable adhesive may be an adhesive containing, as a main component, a thermoplastic resin having a low adhesive force such as beeswax and other wax.

[Variation of Layered Body: 3]

A layered body from which a supporting member separation apparatus separates a support may be, for example, a layered body produced by a production method including the steps described below. A layered body for the present invention may be produced by a production method including (i) a release layer forming step of forming on a support a release layer that becomes altered in response to light irradiation, (ii) an adhesive layer forming step of forming an adhesive layer on the release layer by applying an adhesive composition for forming the adhesive layer, (iii) a curing step of curing the adhesive layer by heating the adhesive layer or exposing the adhesive layer to light, and (iv) a stacking step of placing a substrate on the adhesive layer, the stacking step including a rewiring layer forming step of forming a rewiring layer on the adhesive layer, a mounting step of mounting an element on the rewiring layer, a sealing step of sealing up the element on the rewiring layer with use of a sealing material, and a thinning step of thinning the substrate. The adhesive layer after the curing step preferably has a dynamic viscosity of not less than 1000 Pa· at 250° C. and a Young's modulus of not less than 2 GPa at 25° C. This allows a layered body to be formed suitably. The release layer forming step and the adhesive layer forming step may be carried out in any order or may even be carried out simultaneously, as long as the release layer forming step and the adhesive layer forming step are carried out before the stacking step and the curing step. The curing step is carried out after the stacking step.

A layered body for the present invention may be, in other words, a layered body that includes such members placed on top of each other as a support and instead of the above substrate, a sealed substrate including an element, a sealing material for sealing up the element, and a rewiring layer on which the element is mounted. More specifically, a layered body for the present invention may be a layered body based on fan-out technique, the layered body including elements sealed up with a sealing material in a chip area and a terminal relocated outside the chip area for integration, thinning, and miniaturization of semiconductor devices. Examples of fan-out technique include (i) a fan-out wafer level package intended to arrange semiconductor devices on a wafer and package the semiconductor devices and (ii) a fan-out wafer level package intended to arrange semiconductor devices on a panel and package the semiconductor devices.

The release layer forming step involves forming, on a flat surface of a support that transmits light, a release layer that becomes altered in response to light irradiation. The adhesive layer forming step involves forming an adhesive layer on a flat surface of a substrate by applying an adhesive composition to the flat surface. The adhesive composition contains a polymerizable resin component, a polymerization initiator, and a solvent. The polymerization initiator contained in the adhesive composition may be a thermal polymerization initiator or a photopolymerization initiator, preferably a thermal polymerization initiator. The adhesive composition may be applied to the flat surface by, for example, a publicly known method such as spin coating method, dipping method, roller blade method, spraying application method, and slitting application method. The adhesive layer forming step preferably involves, after applying the adhesive composition to the substrate, removing the solvent in advance. The stacking step involves placing the substrate, the adhesive layer, the release layer, and the support on top of each other in this order. The curing step involves curing the polymerizable resin component in the adhesive layer through polymerization by heating the adhesive layer in the layered body prepared through the stacking step or exposing the adhesive layer to light. The rewiring layer forming step involves forming a rewiring layer on the adhesive layer. The rewiring layer is also called redistribution layer (RDL). The rewiring layer is a thin-film wiring body that provides wiring for connection to elements, and may be structured to have a single layer or a plurality of layers. The rewiring layer may be formed through a procedure used in a publicly known semiconductor process. The mounting step involves mounting elements on the rewiring layer. Elements may be mounted with use of, for example, a chip mounter. More specifically, elements may be mounted on the rewiring layer via, for example, solder bumps. The sealing step involves sealing up the elements with a sealing material. Examples of the sealing material include an epoxy-based resin and a silicone-based resin. The thinning step involves thinning the sealing material to suitably form on the adhesive layer a sealed substrate including a rewiring layer.

<Supporting Member Separation Apparatus According to a Second Embodiment>

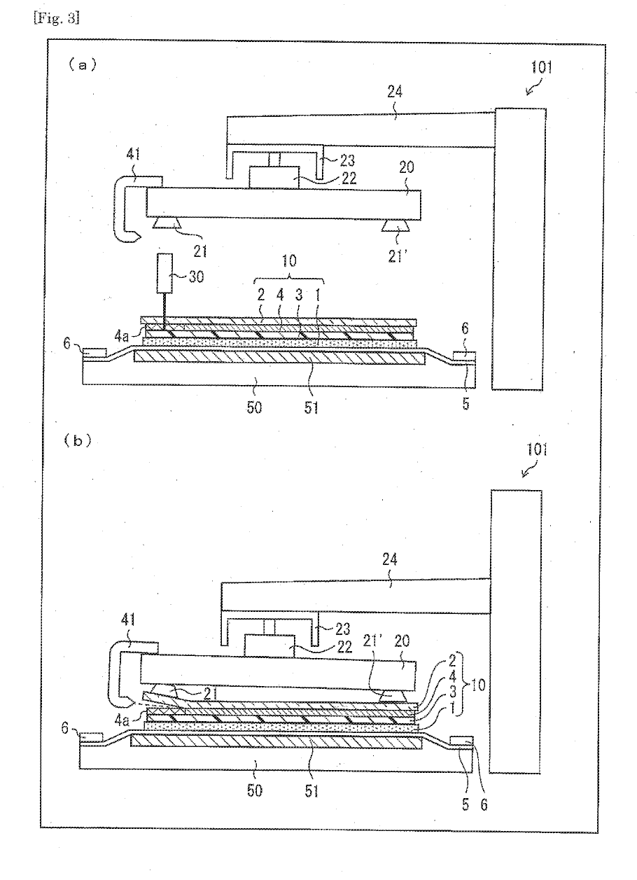

The supporting member separation method according to the present invention is not limited to the above-described embodiment (that is, the first embodiment). A supporting member separation apparatus 101 according to an embodiment (second embodiment) is configured to, for instance, include a fluid nozzle (fluid injecting section) 41 that is configured to be lifted and lowered by the lifting and lowering section 24 together with the first holding section 21 as illustrated in (a) and (b) of FIG. 3. The supporting member separation apparatus 101 according to the present embodiment is identical in configuration to the supporting member separation apparatus 100 except for the fluid nozzle 41. The description below will thus not deal with members other than the fluid nozzle 41.

As illustrated in (a) of FIG. 3, the supporting member separation apparatus 101 is configured such that the fluid nozzle 41, which is configured to inject a fluid, is provided on the plate section 20 and above the first holding section 21. Thus, lifting and lowering the first holding section 21 with use of the lifting and lowering section 24 lifts and lowers the fluid nozzle 41 as well. With this configuration, when the supporting member separation apparatus 101 separates the support plate 2 from the rest of the layered body 10 on the stage 50 and carries the support plate 2 out of the supporting member separation apparatus 101 with use of the first holding section 21 and the second holding section 21′, the fluid nozzle 41 can also be moved away from the vicinity of the substrate 1 remaining on the stage 50. The above configuration thus eliminates the need to include an additional driving system for moving the fluid nozzle from above the stage 50 when another process is to be carried out on the substrate 1 remaining on the stage 50.

As illustrated in (b) of FIG. 3, the fluid nozzle 41 is positioned such that when the plate section 20 has been lifted to hold and lift the support plate 2 with use of the first holding section 21, the tip of the fluid nozzle 41 is directed to a gap formed at a portion at which a portion of the substrate 1 and a portion of the support plate 2 sandwich the region 4a of the release layer 4. This configuration makes it possible to, when the support plate 2 has been lifted to form a gap between the substrate 1 and the support plate 2, rapidly inject a fluid into the layered body 10 through the gap.

<Supporting Member Separation Apparatus According to a Third Embodiment>

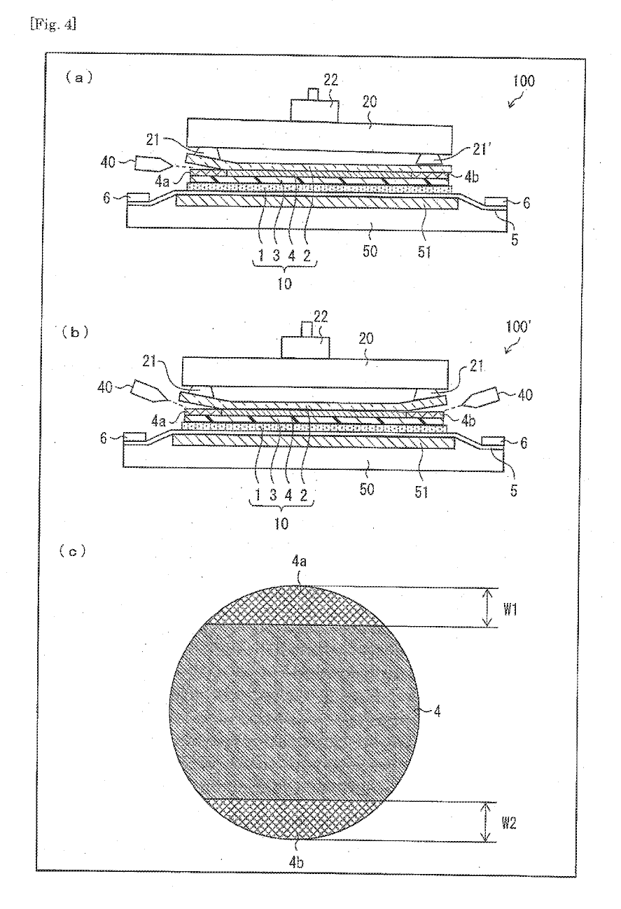

A supporting member separation apparatus according to the present invention is not limited to the above-described embodiments (that is, the first and second embodiments). The supporting member separation apparatus 100 of the third embodiment is configured, for instance, such that the light emitting section 30 emits light to a plurality of regions 4a and 4b in a peripheral portion of the release layer 4 as illustrated in (a) and (c) of FIG. 4. Such light emission alters the plurality of regions 4a and 4b in a peripheral portion of the release layer 4 as illustrated in (c) of FIG. 4. The supporting member separation apparatus according to the third embodiment is identical to the supporting member separation apparatus 100 according to the first embodiment except that the light emitting section 30 emits light to a plurality of regions 4a and 4b of the release layer 4 through the support plate 2. The region 4b has a width W2 within a range equal to the range of the width W1 of the region 4a. The substrate 1 has a region facing the region 4b of the release layer 4 which region is a non-circuitry region, in which no structures such as an integrated circuit are present.

The above configuration makes it possible to alter a larger region in a peripheral portion of the release layer 4 in the layered body 10. This makes it easy, as compared to a case where only the region 4a of the release layer 4 has been altered, to separate the support plate 2 from the rest of the layered body 10 when a fluid is injected from the fluid nozzle 40 as illustrated in (a) of FIG. 4.

<Variation of the Supporting Member Separation Apparatus According to the Third Embodiment>

A supporting member separation apparatus 100′ as a variation of the supporting member separation apparatus 100 according to the third embodiment includes a plurality of first holding sections 21 and a plurality of fluid nozzles 40. The plurality of first holding sections 21 each (i) hold the support plate 2 by coming into contact with a surface portion of the support plate 2 which surface portion is opposite to a corresponding one of the plurality of regions 4a and 4b (that is, altered regions of the release layer 4) and (ii) lift the support plate 2 to form a gap between a portion of the substrate 1 and a portion of the support plate 2 which portions sandwich the corresponding one of the plurality of regions 4a and 4b. The supporting member separation apparatus 100′ is configured to inject a fluid into the layered body 10 simultaneously from each of the fluid nozzles 40 through a corresponding one of the plurality of gaps.

The above configuration allows a fluid to be injected into the layered body 10 simultaneously through a plurality of gaps formed between the substrate 1 and the support plate 2, and thereby makes it possible to more uniformly apply a force to the support plate 2 for the separation of the support plate 2 from the rest of the layered body 10. Further, the above configuration allows the support plate 2 to be held by a plurality of first holding sections 21. This can more suitably prevent the support plate 2, as separated from the rest of the layered body 10 through the fluid injection, from being moved away from the supporting member separation apparatus 100 due to the pressure of the fluid injected from the fluid nozzles 40.

<Supporting Member Separation Apparatus According to a Fourth Embodiment>

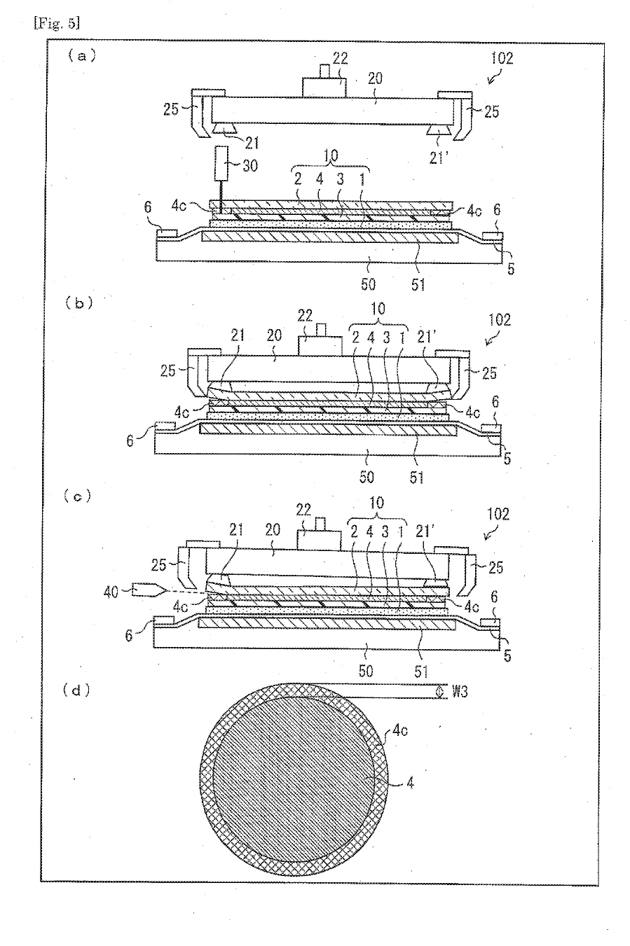

A supporting member separation apparatus according to the present invention is not limited to the above-described embodiments (that is, the first to third embodiments). For instance, a supporting member separation apparatus 102 according to an embodiment (that is, the fourth embodiment), as illustrated in (a) of FIG. 5, further includes a clamp (clamping section) 25 configured to clamp and lift an outer peripheral edge of the support plate 2 to increase a gap, in the depth direction thereof, formed between a portion of the substrate 1 and a portion of the support plate 2 which portions sandwich an altered region 4c of the release layer 4. The supporting member separation apparatus 102 is configured such that the first holding section 21 is configured to (i) hold the support plate 2 from a side of a surface portion of the support plate 2 which surface portion is opposite to a surface portion of the support plate 2 which surface portion faces the gap as increased in its depth direction and (ii) lift the support plate 2. The supporting member separation apparatus 102 according to the present embodiment is identical in configuration to the supporting member separation apparatus 100 except for the region 4c of the release layer 4, which region 4c is irradiated with light, and the clamp 25. The description below will thus not deal with members other than the region 4c and the clamp 25.

As illustrated in (a) of FIG. 5, the supporting member separation apparatus 102 according to the present embodiment is configured to emit light to the region 4c of the release layer 4 to alter the region 4c of the release layer 4. As illustrated in (d) of FIG. 5, the region 4c has a width W3 extending inward from the outer peripheral edge of the release layer 4 which width W3 is within a range of not less than 0.1 mm and not more than 2.0 mm. The supporting member separation apparatus 102 according to the present embodiment is, in other words, configured to emit no light to a region of the release layer which region is inward of a region extending inward from the outer peripheral edge of the release layer 4 by 2.0 mm. This can prevent light from being emitted to an inner region of the substrate 1 (that is, a circuitry region), thereby preventing the light from damaging the inner region.

The clamp 25 is movable in a direction parallel to the plane of the support plate 2 and toward the outer peripheral edge of the support plate 2 in the layered body 10 which support plate 2 is held by the first holding section 21. This movement causes the clamp 25 to clamp the outer peripheral edge of the support plate 2 in the layered body 10 fixed to the stage 50. Subsequently lifting the lifting and lowering section 24 causes the clamp 25 to lift the outer peripheral edge of the support plate 2. This increases the gap, which has been formed between a portion of the substrate 1 and a portion of the support plate 2 which portions sandwich the altered region 4c of the release layer 4, in the depth direction of the gap (see (b) of FIG. 5). Thus, in a case where the region 4c of the release layer 4, which region 4c is to be altered, has a small width W3, the above configuration makes it possible to deepen the gap between the substrate 1 and the support plate 2 over the width W3 of the region 4c. Holding the support plate 2 from a side of a surface portion of the support plate 2 which surface portion is opposite to a surface portion of the support plate 2 which surface portion faces the gap as increased in its depth direction and lifting the support plate 2 makes the gap larger and thereby allows a fluid to be injected from the fluid nozzle 40 suitably into the layered body 10 (see (c) of FIG. 5). The supporting member separation apparatus 102 according to the present embodiment, in other words, causes light to be emitted to only a small area on the release layer 4 in the layered body 10, and thereby makes it possible to (i) reduce the area on the substrate 1 which area is irradiated with light and is damaged and also (ii) successfully separate the support plate 2 from the rest of the layered body 10.

<Supporting Member Separation Method>

A supporting member separation method according to an embodiment of the present invention is a supporting member separation method for separating, from a layered body 10, a support plate 2 (support) that transmits light, the layered body 10 including (i) a substrate 1, (ii) the support plate 2, and between the substrate 1 and the support plate 2, (iii) an adhesive layer 3 and (iv) a release layer 4 that becomes altered in response to light irradiation, the supporting member separation method including: a light emitting step of emitting light through the support plate 2 to at least a partial region 4a of a peripheral portion of the release layer 4 so as to alter the region 4a; and a separating step of (i) holding the support plate 2 from a side of a surface portion of the support plate 2 which surface portion is opposite to a surface portion of the support plate 2 which surface portion faces the region 4a as altered and lifting the support plate 2 so as to form a gap between a portion of the substrate 1 and a portion of the support plate 2 which portions sandwich the region 4a as altered and (ii) injecting a fluid into the layered body 10 through the gap so as to separate the support plate 2 from the layered body 10. The supporting member separation apparatuses 100, 100′, 101, and 102 described above are each an embodiment of a supporting member separation apparatus for use in a supporting member separation method according to the present invention. Embodiments of a supporting member separation method according to the present invention may be described similarly to the above embodiments and in FIGS. 1 to 5.

A supporting member separation method according to an embodiment may be configured such that the light emitting step involves emitting light to a plurality of regions 4a and 4b of the peripheral portion of the release layer 4 as illustrated in (a) and (c) of FIG. 3.

The supporting member separation method for a layered body that does not include a release layer and that includes an adhesive layer which is in direct contact with the substrate and the support plate and which has an adhesive force that allows the support plate to be stripped off by a mechanical force is a supporting member separation method for separating a support plate 2 from a layered body including a substrate 1, the support plate 2, and an adhesive layer 3 between the substrate 1 and the support plate 2, the support plate 2 supporting the substrate 1, the supporting member separation method including: a separating step of (i) holding the support plate 2 from a side of a surface portion of the support plate 2 which surface portion is opposite to a surface portion of the support plate 2 which surface portion faces a portion of the adhesive layer 3 and lifting the support plate 2 so as to form a gap between a portion of the substrate 1 and a portion of the support plate 2 which portions sandwich the portion of the adhesive layer 3 and (ii) injecting a fluid into the layered body through the gap so as to separate the support plate 2 from the layered body. In this case, the separating step preferably involves holding and lifting an outer peripheral edge of the support plate 2 so as to form the gap.

In a case where a layered body for the present invention is a layered body based on fan-out technique, that is, a layered body that includes members such as a support and a sealed substrate including a rewiring layer which members are placed on top of each other, a supporting member separation method according to the present invention is used to separate a support from a layered body including members such as the support and a sealed substrate including a rewiring layer.

A supporting member separation method according to another embodiment may be configured to, as illustrated in (b) and (c) of FIG. 4, (i) hold the support plate 2 by coming into contact with surface portions of the support plate 2 which surface portions are each opposite to a corresponding one of the plurality of regions 4a and 4b (that is, altered regions of the release layer 4) and (ii) lift the support plate 2 to form a plurality of gaps each between a portion of the substrate 1 and a portion of the support plate 2 which portions sandwich a corresponding one of the plurality of regions 4a and 4b, and inject a fluid into the layered body 10 simultaneously through the plurality of gaps.

A supporting member separation method according to still another embodiment may be configured as illustrated in (a) to (d) of FIG. 5 such that the separating step involves (i) clamping and lifting an outer peripheral edge of the support so as to increase the gap, in the depth direction thereof, between a portion of the substrate 1 and a portion of the support plate 2 which portions sandwich the region 4c as altered and (ii) after increasing the gap in the depth direction thereof, holding the support plate 2 from a side of a surface portion of the support plate 2 which surface portion is opposite to a surface portion of the support plate 2 which surface portion faces the gap as increased in the depth direction and lifting the support.

A supporting member separation method according to still another embodiment may be configured as illustrated in (a) to (d) of FIG. 2 such that the separating step involves, while the substrate 1 is fixed, holding the support plate 2 and lifting the support plate 2 from the substrate 1 so as to form a gap between a portion of the substrate 1 and a portion of the support plate 2 which portions sandwich the region 4a as altered.

A supporting member separation method according to any of the above embodiments is preferably configured such that the fluid is at least one selected from the group consisting of air, dry air, nitrogen, and argon.

The present invention is not limited to the embodiments, but can be altered by a skilled person in the art within the scope of the claims. The present invention also encompasses, in its technical scope, any embodiment derived by combining technical means disclosed in differing embodiments.

### Examples

<Evaluation of Separability of Support: 1>

The separability for a layered body was evaluated as Example 1 with use of the supporting member separation apparatus 100 illustrated in (a) of FIG. 1.

[Preparation of Layered Body] A semiconductor wafer substrate (12 inches, silicon) was spin-coated with TZNR (registered trademark)-A4017 (available from Tokyo Ohka Kogyo Co., Ltd.), and the resultant product was baked at the temperatures of 90° C., 160° C., and 220° C. each for 4 minutes, whereby an adhesive layer was formed (thickness of 50 μm). Then, while the semiconductor wafer substrate on which the adhesive layer had been formed was being rotated at 1,500 rpm, TZNR (registered trademark)-HC thinner ((available from Tokyo Ohka Kogyo Co., Ltd.) was supplied at a supply rate of 10 cc/min with use of an EBR nozzle for 5 minutes to 15 minutes. This operation removed a peripheral portion of the adhesive layer formed on the semiconductor wafer substrate which peripheral portion extended inward from the edge of the semiconductor wafer substrate by 1.3 mm.

Next, with use of a bare glass support (12 inches, thickness of 400 μm) as a support, a release layer was formed on the support by a plasma CVD method using fluorocarbon. The release layer formation was carried out under the conditions of a flow rate of 400 sccm, a pressure of 700 mTorr, a high-frequency electric power of 3,000 W, and a film forming temperature of 240° C. C₄F₈ was used as a reaction gas. A fluorocarbon film (thickness of 0.5 μm) as a release layer was formed on the support by CVD method.

Next, the semiconductor wafer substrate, the adhesive layer, the release layer, and the glass support were stacked in this order. The resultant product was preheated at 215° C. for 180 seconds in vacuum, and was then pressed for 360 seconds at an attaching pressure of 2,000 kgf so that the glass support and the semiconductor wafer substrate were attached to each other. These operations prepared a layered body. Then, a thinning (50 m) process was carried out on the back surface of the semiconductor wafer substrate of the layered body with use of a back grinding apparatus available from DISCO Corporation.

[Separation of Support: 1]

Example 1 evaluated the separability of the support with use of the supporting member separation apparatus 100 with variations of (i) the width W1 illustrated in (b) of FIG. 1 of the region 4a to be irradiated with laser light and (ii) the pressure of blowing dry air from an air nozzle. The first holding section 21 lifted a portion of the glass support which portion coincided with the region 4a of the release layer to a height of 0.5 mm from the initial state to form a gap between a portion of the semiconductor wafer substrate and a portion of the glass support through which gap dry air was to be blown.

The laser light emitted had a wavelength of 532 nm and a repetition frequency of 40 kHz. Table 1 below shows evaluation conditions and evaluation results for Example 1. The separability was evaluated as “good (G)” in a case where the glass support was separated immediately after a single operation of dry air blowing, “fair (F)” in a case where the glass support was separated through three operations of dry air blowing, or “poor (P)” in a case where the glass support was not separated. The symbol “-” for condition 1 in Table 1 indicates that air was not blown.

TABLE 1

| | Laser irradiation | Air pressure | |
|---|---|---|---|
| | width W1 (mm) | (MPa) | Separability |
| Condition 1 | 8 | — | P |
| Condition 2 | 8 | 0.2 | G |
| Condition 3 | 6 | 0.2 | P |
| Condition 4 | 6 | 0.3 | G |

The results for conditions 2 to 4 in Table 1 prove that either in a case where the laser light emitted has a width W1 of not less than 6 mm or in a case where the air pressure is not less than 0.3 MPa, the glass support is successfully separated from the rest of the layered body immediately after air is blown.

<Evaluation of Separability of Support: 2>

The separability for a layered body was evaluated as Example 2 with use of the supporting member separation apparatus 102 illustrated in (a) of FIG. 5. The separability of a support from the same layered body was evaluated as Comparative Example 1 with use of a supporting member separation apparatus free from a first holding section and including a release plate configured to clamp the support with use of only a clamp.

The layered body used for the evaluation of the separability of a support was identical to that used in Example 1, and is not described again here.

[Separation of Support: 2]

Example 2 evaluated the separability of a support with use of the supporting member separation apparatus 102 with variations of the height to which a portion of the glass support was lifted from the rest of the layered body with use of the clamp 25. First, the layered body was irradiated with laser light while the width W3 illustrated in (d) of FIG. 5 of the region 4c for the irradiation with laser light was set at 2 mm. Then, a portion of the glass support was lifted with use of the clamp 25. The depth of the gap between a portion of the semiconductor wafer substrate and the portion of the glass support was measured. Subsequently, the portion of the glass support was lifted to a height of 0.5 mm with use of the first holding section 21. Dry air was blown through the gap formed between the portion of the semiconductor wafer substrate and the portion of the glass support. The dry air blown from an air nozzle constantly had a pressure of 0.3 MPa.

In Example 2 and Comparative Example 1, the laser light emitted had a wavelength of 532 nm and a repetition frequency of 40 kHz. The supporting member separation apparatus of Comparative Example 1 for separating a support with use of a clamp did not blow dry air from an air nozzle for the separation of the glass support.

The separability was evaluated under the same conditions as those for Example 1.

Table 2 below shows evaluation conditions and evaluation results for Example 2 and Comparative Example 1.

TABLE 2

| | | Lifting height | Gap depth | |
|---|---|---|---|---|
| | | (mm) | (mm) | Separability |
| Example 2 | Condition 1 | 1 | 21 | G |
| | Condition 2 | 0.7 | 20 | G |
| | Condition 3 | 0.5 | 13 | G |
| | Condition 4 | 0.3 | 8 | F |

| | | | |
|---|---|---|---|
| Comparative Example 1* | 5 | — | P |

*No dry air blowing

The results shown in Table 2 prove that lifting the glass support with use of the clamp 25 may cause (i) the gap between a portion of the semiconductor wafer substrate of the layered body and a portion of the glass support of the layered body to be deeper than the width W3 (2 mm) of the region 4c and (ii) the glass support to be separated. The results also prove that under conditions 1 to 3 for Example 2, the glass support may be separated (“G”) immediately after a single operation of dry air blowing.

The comparative example proves that in a case where dry air is not blown and in particular, the glass support is thin (400 μm), the glass support may be damaged.

Each supporting member separation apparatus according to the present invention has proven to be capable of successfully separating a glass support from the rest of a layered body within a short time period.

### INDUSTRIAL APPLICABILITY

The present invention is suitably applicable to a process of producing a fine semiconductor device.

### REFERENCE SIGNS LIST

1 Substrate
2 Support plate (support)
3 Adhesive layer
4 Release layer
4a Region (release layer)
4b Region (release layer)
4c Region (release layer)
10 Layered body
21 First holding section
21′ Second holding section
24 Lifting and lowering section
30 Light emitting section
40 Fluid nozzle (fluid injecting section)
50 Stage (fixing section)
51 Porous portion (fixing section)
100 Supporting member separation apparatus
100′ Supporting member separation apparatus
101 Supporting member separation apparatus
102 Supporting member separation apparatus

1. A supporting member separation apparatus configured to separate, from a layered body, a support that transmits light, the layered body including (i) a substrate, (ii) the support, and between the substrate and the support, (iii) at least a release layer that becomes altered in response to light irradiation,
the supporting member separation apparatus comprising:
a light emitting section configured to emit light through the support to at least a partial region of a peripheral portion of the release layer so as to alter the partial region;
at least one first holding section configured to, in such a manner as to form a gap between a portion of the substrate and a portion of the support which portions sandwich the partial region as altered, (i) hold the support from a side of a surface portion of the support which surface portion is opposite to a surface portion of the support which surface portion faces the partial region as altered and (ii) lift the support; and
at least one fluid injecting section configured to inject a fluid into the layered body through the gap in such a manner as to separate the support from the layered body.

2. The supporting member separation apparatus according to claim 1, wherein
the light emitting section is configured to emit light to a plurality of regions of the peripheral portion of the release layer.

3. The supporting member separation apparatus according to claim 2, wherein
the at least one first holding section includes a plurality of first holding sections;
the at least one fluid injecting section includes a plurality of fluid injecting sections;
the plurality of first holding sections are configured to, in such a manner as to form respective gaps each between a portion of the substrate and a portion of the support which portions sandwich a corresponding one of the plurality of regions as altered, each (i) hold the support from a side of a first surface portion of the support which first surface portion is opposite to a second surface portion of the support which second surface portion faces the corresponding one of the plurality of regions as altered and (ii) lift the support; and
the plurality of fluid injecting sections are configured to each simultaneously inject the fluid into the layered body through a corresponding one of the gaps.

4. The supporting member separation apparatus according to any one of claims 1 to 3, further comprising:
a clamping section configured to clamp and lift an outer peripheral edge of the support so as to increase the gap(s), in a depth direction thereof, formed between the portion(s) of the substrate and the portion(s) of the support which portions sandwich the partial region (or the plurality of regions) as altered, wherein
the at least one first holding section is configured to (i) hold the support from the side of the (first) surface portion of the support which (first) surface portion is opposite to the (second) surface portion of the support which (second) surface portion faces the gap(s) as increased in the depth direction and (ii) lift the support.

5. The supporting member separation apparatus according to any one of claims 1 to 4, further comprising:
a fixing section configured to fix the substrate, wherein
while the substrate is fixed by the fixing section, the at least one first holding section holding the support lifts the portion(s) of the support from the substrate so as to form the gap(s) between the portion(s) of the substrate and the portion(s) of the support which portions sandwich the partial region (or the plurality of regions) as altered.

6. The supporting member separation apparatus according to any one of claims 1 to 5, wherein
the at least one first holding section is configured to hold the support by vacuum suction.

7. The supporting member separation apparatus according to any one of claims 1 to 6, further comprising:
a lifting and lowering section configured to lift and lower the at least one first holding section, wherein
the lifting and lowering section lifts the at least one first holding section, holding the support, so as to form the gap(s) between the portion(s) of the substrate and the portion(s) of the support which portions sandwich the partial region (or the plurality of regions) as altered.

8. The supporting member separation apparatus according to claim 7, wherein
the at least one fluid injecting section is lifted and lowered by the lifting and lowering section together with the at least one first holding section.

9. The supporting member separation apparatus according to any one of claims 1 to 8, further comprising:
a plurality of second holding sections each configured to hold a peripheral portion of the support.

10. The supporting member separation apparatus according to any one of claims 1 to 9, wherein
the fluid is at least one selected from the group consisting of air, dry air, nitrogen, and argon.

11. The supporting member separation apparatus according to any one of claims 1 to 10, wherein
the layered body further includes an adhesive layer between the substrate and the support.

12. A supporting member separation apparatus configured to separate a support from a layered body including a substrate, the support, and an adhesive layer between the substrate and the support, the support supporting the substrate,
the supporting member separation apparatus comprising:
a fixing section configured to fix the layered body on a side of the substrate;
a first holding section configured to, in such a manner as to form a gap between a portion of the substrate and a portion of the support which portions sandwich a portion of the adhesive layer, (i) hold the support from a side of a surface portion of the support which surface portion is opposite to a surface portion of the support which surface portion faces the portion of the adhesive layer and (ii) lift the support; and
a fluid injecting section configured to inject a fluid into the layered body through the gap in such a manner as to separate the support from the layered body.

13. The supporting member separation apparatus according to claim 12, wherein
the first holding section is configured to clamp and lift an outer peripheral edge of the support so as to form the gap.

14. A supporting member separation method for separating, from a layered body, a support that transmits light, the layered body including (i) a substrate, (ii) the support, and between the substrate and the support, (iii) at least a release layer that becomes altered in response to light irradiation, the supporting member separation method comprising:
a light emitting step of emitting light through the support to at least a partial region of a peripheral portion of the release layer so as to alter the partial region; and
a separating step of (i) holding the support from a side of a surface portion of the support which surface portion is opposite to a surface portion of the support which surface portion faces the partial region as altered and lifting the support so as to form a gap between a portion of the substrate and a portion of the support which portions sandwich the partial region as altered and (ii) injecting a fluid into the layered body through the gap so as to separate the support from the layered body.

15. The supporting member separation method according to claim 14, wherein
the light emitting step involves emitting light to a plurality of regions of the peripheral portion of the release layer.

16. The supporting member separation method according to claim 15, wherein
the support is (i) held, in such a manner as to form a plurality of gaps each between a portion of the substrate and a portion of the support which portions sandwich a corresponding one of the plurality of regions as altered, from a side of a first surface portion of the support which first surface portion is opposite to a second surface portion of the support which second surface portion faces the corresponding one of the plurality of regions as altered and is (ii) lifted; and
the fluid is injected into the layered body simultaneously through the plurality of gaps.

17. The supporting member separation method according to any one of claims 14 to 16, wherein
the separating step involves (i) clamping and lifting an outer peripheral edge of the support so as to increase the gap(s), in a depth direction thereof, between the portion(s) of the substrate and the portion(s) of the support which portions sandwich the partial region (or the plurality of regions) as altered and after increasing the gap(s) in the depth direction thereof, (ii) holding the support from the side of the (first) surface portion of the support which (first) surface portion is opposite to the (second) surface portion of the support which (second) surface portion faces the gap(s) as increased in the depth direction and lifting the support.

18. The supporting member separation method according to any one of claims 14 to 17, wherein
the separating step involves, while the substrate is fixed, holding the support and lifting the support from the substrate so as to form the gap(s) between the portion(s) of the substrate and the portion(s) of the support which portions sandwich the partial region (or the plurality of regions) as altered.

19. The supporting member separation method according to any one of claims 14 to 18, wherein
the fluid is at least one selected from the group consisting of air, dry air, nitrogen, and argon.

20. A supporting member separation method for separating a support from a layered body including a substrate, the support, and an adhesive layer between the substrate and the support, the support supporting the substrate, the supporting member separation method comprising:
a separating step of (i) holding the support from a side of a surface portion of the support which surface portion is opposite to a surface portion of the support which surface portion faces a portion of the adhesive layer and lifting the support so as to form a gap between a portion of the substrate and a portion of the support which portions sandwich the portion of the adhesive layer and (ii) injecting a fluid into the layered body through the gap so as to separate the support from the layered body.

21. The supporting member separation method according to claim 20, wherein
the separating step involves holding and lifting an outer peripheral edge of the support so as to form the gap.
